(19) United States
(12) Patent Application Publication
(10) Pub. No.: US 2025/0273428 A1
(43) Pub. Date: Aug. 28, 2025

(54) PLASMA ADJUSTMENT USING SOURCE-LESS RESONANT STRUCTURE

(71) Applicant: Tokyo Electron Limited, Tokyo (JP)

(72) Inventors: Barton Lane, Austin, TX (US); John Carroll, Austin, TX (US); Jianping Zhao, Austin, TX (US)

(21) Appl. No.: 18/817,042

(22) Filed: Aug. 27, 2024

Related U.S. Application Data
(60) Provisional application No. 63/558,450, filed on Feb. 27, 2024.

(51) Int. Cl. H01J 37/32; H01P 3/12

(52) U.S. Cl. CPC H01J 37/321; H01P 3/12

(57) ABSTRACT

A plasma processing apparatus includes a plasma processing chamber, a radio frequency waveguide, and a resonant structure. The plasma processing apparatus is configured to generate a plasma within the plasma processing chamber using a radio frequency field propagating through the radio frequency waveguide. The plasma includes a plasma sheath extending laterally along a surface of the radio frequency waveguide. The resonant structure is disposed in the radio frequency field and configured to induce localized effects in the plasma using current induced in the resonant structure by the radio frequency field.

This application claims priority to Provisional Application No. 63/558,450, filed on Feb. 27, 2024. The disclosure of the aforementioned application is hereby incorporated by reference in its entirety.

### TECHNICAL FIELD

The present invention relates generally to the adjustment of characteristics of a plasma, and, in particular embodiments, to systems, apparatuses, and methods for adjusting uniformity of a plasma using resonant structures.

### BACKGROUND

Microelectronic device fabrication typically involves a series of manufacturing techniques that include formation, patterning, and removal of a number of layers of material on a substrate. Plasma processing is used extensively in the manufacturing and fabrication of microelectronic circuits and generally within the semiconductor industry. For example, plasma may be used in etching, deposition, for cleaning, surface oxidation, sputtering, and others. In a plasma processing system, alternating current (AC) power, usually radio frequency (RF) power, is coupled to a plasma processing chamber to generate plasma by ionizing a gas. Various coupling mechanisms may be used, resulting in a variety of categories of plasma that tend of have certain properties, including capacitively coupled plasma (CCP), inductively coupled plasma (ICP), and surface wave plasma (SWP), among others.

RF power coupled to the plasma processing chamber to generate plasma is typically referred to as source power. Often, high frequency RF power is used, such as in the high frequency (HF), very high frequency (VHF), and ultra high frequency (UHF) portions of the electromagnetic spectrum. Many factors are considered when determining the source power frequency in a given plasma processing system. For example, the frequency of the source power can impact plasma properties such as ion energy and fluxes of ions and radicals as well as influencing cost, maintenance, and manufacturability of the plasma equipment.

Plasma uniformity (i.e., the consistency of various plasma properties such as densities, fluxes, and temperatures for ions, electrons, and neutrals across the surface of a substrate being processed) is a universal challenge during plasma processes. For example, RF power propagating through the plasma processing chamber can form standing waves that disrupt the uniformity of the plasma profile. One common non-uniform plasma profile has elevated plasma density in the center region of the plasma that falls off toward the edge regions (referred to as a center-peaked plasma). In many cases, a flat plasma profile (as opposed to a center-peaked plasma profile) is desirable.

However, some processes require more than achieving and maintaining a uniform plasma profile, such as the ability to adjust plasma properties with spatial control in desired regions of a substrate. For example, it can be desirable to alter the plasma properties only in some regions of the plasma, or for the plasma properties to evolve at different speeds for different regions over the course of a plasma process.

Although plasma uniformity can be a challenge at any frequency, increasing the source power frequency can make uniformity challenges more difficult. In some cases, higher frequency source power becomes nonviable because of the nonuniformity of the plasma. On the other hand, plasmas generated with higher frequency source power may have a variety of beneficial qualities, such as desirable ion energy and high ion and radical fluxes. Therefore, improved systems, apparatuses, and methods for controlling the plasma profile may be desirable.

### SUMMARY

In accordance with an embodiment of the invention, a plasma processing apparatus includes a plasma processing chamber, a radio frequency (RF) waveguide, and a resonant structure. The plasma processing apparatus is configured to generate a plasma within the plasma processing chamber using an RF field propagating through the RF waveguide. The plasma includes a plasma sheath extending laterally along a surface of the RF waveguide. The resonant structure is disposed in the RF field and configured to induce localized effects in the plasma using current induced in the resonant structure by the RF field.

In accordance with another embodiment of the invention, a plasma processing apparatus includes a source electrode including an upper conductive surface and a lower conductive surface, a grounded conductive surface disposed above the upper conductive surface, where the grounded conductive surface and the upper conductive surface together form an RF waveguide, and a resonant structure. The plasma processing apparatus is configured to generate a plasma below the lower conductive surface using RF source power directly coupled to the source electrode that generates an RF field propagating through the RF waveguide. The resonant structure is disposed in the RF waveguide and includes a current-carrying element configured to induce localized effects in the plasma using the current induced in the current-carrying element by the RF field.

In accordance with still another embodiment of the invention, a method of adjusting plasma includes generating a plasma using RF source power that includes a source power frequency, and inducing a current in a resonant structure using an RF field propagated through an RF waveguide by the RF source power. The resonant structure is located within the RF field and is electrically insulated from the RF source power. The current in the resonant structure induces localized effects in the plasma. The method further includes adjusting the localized effects in the plasma by changing one or more of the source power frequency or capacitance of the resonant structure.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example plasma processing apparatus that includes a resonant structure disposed within an RF field propagating between an RF driven structure and a grounded structure that together from an RF waveguide in accordance with embodiments of the invention;

FIG. 2 illustrates an example plasma processing apparatus that includes resonant structure disposed within an RF field propagating through an RF waveguide and a source electrode separated from a grounded chamber wall by a dielectric spacer in accordance with embodiments of the invention;

FIG. 3 illustrates an example plasma processing apparatus that includes resonant structure disposed within an RF field propagating through an RF waveguide where the resonant structure is configured to directly induce localized effects in a plasma in accordance with embodiments of the invention;

FIG. 4 illustrates an example plasma processing apparatus that includes resonant structure disposed within an RF field propagating through an RF waveguide where the resonant structure is configured to indirectly induce inductive localized effects in a plasma in accordance with embodiments of the invention;

FIG. 5 illustrates an example plasma processing apparatus that includes resonant structure disposed within an RF field propagating through an RF waveguide where the resonant structure is configured to indirectly induce capacitive localized effects in a plasma in accordance with embodiments of the invention;

FIG. 6 illustrates an equivalent circuit of an example resonant structure that includes a current-carrying element capacitively coupled to a grounded surface on both ends in accordance with embodiments of the invention;

FIGS. 7A and 7B illustrate an example plasma processing apparatus that includes an L-shaped resonant structure where FIG. 7A shows a side view and FIG. 7B shows a corresponding overhead view in accordance with embodiments of the invention;

FIGS. 8A and 8B illustrate 3D views of a specific implementation of an example plasma processing apparatus that includes an L-shaped resonant structure where FIG. 8A shows the resonant structure and FIG. 8B shows a cutaway view of the plasma processing apparatus in accordance with embodiments of the invention;

FIGS. 9A and 9B illustrate an example plasma processing apparatus that includes a U-shaped resonant structure where FIG. 9A shows a side view and FIG. 9B shows a corresponding overhead view in accordance with embodiments of the invention;

FIGS. 10A and 10B illustrate 3D views of a specific implementation of an example plasma processing apparatus that includes a U-shaped resonant structure where FIG. 10A shows the resonant structure and FIG. 10B shows a cutaway view of the plasma processing apparatus in accordance with embodiments of the invention;

FIGS. 11A and 11B illustrate an example plasma processing apparatus that includes a horseshoe resonant structure where FIG. 11A shows a side view and FIG. 11B shows a corresponding overhead view in accordance with embodiments of the invention;

FIGS. 12A and 12B illustrate 3D views of a specific implementation of an example plasma processing apparatus that includes a horseshoe resonant structure where FIG. 12A shows the resonant structure and FIG. 12B shows a cutaway view of the plasma processing apparatus in accordance with embodiments of the invention;

FIG. 13 illustrates an equivalent circuit of an example resonant structure that includes a current-carrying element capacitively coupled to a grounded surface on one end and electrically coupled to a grounded surface on the other end in accordance with embodiments of the invention;

FIG. 14 illustrates a side view of an example plasma processing apparatus that includes an L-shaped resonant structure directly connected to a grounded surface of a plasma processing chamber in accordance with embodiments of the invention;

FIGS. 15A and 15B illustrate 3D views of a specific implementation of an example plasma processing apparatus that includes an L-shaped resonant structure directly connected to a grounded surface of a plasma processing chamber where FIG. 15A shows the resonant structure and FIG. 15B shows a cutaway view of the plasma processing apparatus in accordance with embodiments of the invention;

FIGS. 16A and 16B illustrate an example plasma processing apparatus that includes an I-shaped resonant structure where FIG. 16A shows a side view and FIG. 16B shows a corresponding overhead view in accordance with embodiments of the invention;

FIG. 17 illustrates a 3D cutaway view of a specific implementation of an example plasma processing apparatus that includes an I-shaped resonant structure capacitively coupled to a grounded surface of a plasma processing chamber in accordance with embodiments of the invention;

FIGS. 18A and 18B illustrate an example plasma processing apparatus that includes a horseshoe resonant structure that has eight horseshoe segments in an RF waveguide filled with a solid transmission material where FIG. 18A shows a side view and FIG. 18B shows a corresponding overhead view in accordance with embodiments of the invention;

FIGS. 19A and 19B illustrate an example plasma processing apparatus that includes an L-shaped resonant structure that has multiple spiral segments in a dielectric ring where FIG. 19A shows a side view and FIG. 19B shows a corresponding overhead view in accordance with embodiments of the invention;

FIGS. 20A and 20B illustrate an example plasma processing apparatus that includes a U-shaped resonant structure that has multiple straight segments supported by a dielectric support material where FIG. 20A shows a side view and FIG. 20B shows a corresponding overhead view in accordance with embodiments of the invention;

FIG. 21 illustrates an example system that includes a resonant structure disposed within an RF field propagating between an upper source electrode and a grounded chamber wall, and a controller operatively coupled to at least one of the resonant structure and an RF power source that is directly coupled to the source electrode in accordance with embodiments of the invention; and

FIG. 22 illustrates an example method of adjusting a plasma using a resonant structure in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

The optimal operating regimes for a variety of plasma processes (such as plasma etching and plasma deposition processes) involve plasmas produced by applying source power with higher frequencies. For example, higher frequency plasma (e.g., VHF plasma) may provide optimum ion energy and high ion and radical fluxes, which may be beneficial for deposition processes, such as plasma-enhanced atomic layer deposition (PE-ALD), which can provide benefits such as improved film quality at lower temperatures. However, high frequency plasmas are strongly center-peaked (e.g., because of standing wave effects that worsen with increased frequency), resulting in good quality films at higher frequencies, but very poor spatial uniformity (e.g., cross-wafer uniformity).

For example, a plasma reactor may have an RF power supply directly coupled to an upper electrode (UEL) disposed in the upper region of a reactor chamber using a coaxial center feed. The RF power supply provides RF source power for plasma generation. The walls of the chamber are grounded and there is a space between the UEL and the reactor chamber ceiling (often filled with air). A dielectric ring may electrically insulate the UEL from the reactor walls and seal the region below the UEL so that a vacuum may be formed.

When the RF source power is turned on, an RF field generated by the RF source power excites a plasma in the reactor chamber. The spaces between the UEL and the chamber walls acts as an RF waveguide for the RF field, which propagates through the space above the UEL, around the UEL, and along the plasma sheath interface towards the center of the reactor chamber. The polarization of the waves is perpendicular to the extent of the plasma sheath because the waves are launched from the outer radial edge of the plasma. A displacement current (capacitive current) flows from the UEL through the plasma and to the grounded chamber walls (i.e., the plasma capacitively coupled, a CCP).

The geometry of the reactor chamber (usually cylindrical) focuses the waves at the center. A standing wave forms and the plasma peaks on axis (and also anywhere there are antinodes in the electric field) causing radial non-uniformity of the plasma profile, which may increase as the source power frequency increases and the RF wavelength becomes shorter (e.g., the problem always exists, and may be worsened for higher frequencies such as VHF frequencies and may continue to worsen the higher the frequency). The profile of the electric field depends on the plasma, and not on the details of the edge launch of the propagating waves. As a result, changing the reactor chamber geometry at the radial edge does not resolve the problem.

In accordance with embodiments herein described, the invention proposes adding resonant structures in an RF field used to generated plasma within a plasma processing chamber. The resonant structures interact with the RF field to produce or manipulate localized electromagnetic fields (i.e., localized effects) in the plasma. The resonant structures are source-less, (i.e., they are not directly connected to any power source, including the RF power source generating the RF field). The resonant structures are configured to resonate (i.e. interact) at a specific frequency or band of frequencies (e.g., by selecting combinations of components, materials, geometries, etc.).

Specifically, in various embodiments, a plasma processing apparatus includes a plasma processing chamber (e.g., a reactor chamber of a CCP reactor) and an RF waveguide (e.g., bounded by conductive surfaces of a source electrode and the plasma processing chamber). The plasma processing apparatus is configured to generate a plasma within the plasma processing chamber using an RF field propagating through the RF waveguide. That is, the plasma has a plasma sheath at an interface between the RF waveguide and the plasma that extends laterally along a surface of the waveguide. The plasma processing apparatus also includes a resonant structure located in the RF field and configured to induce localized effects in the plasma using current induced in the resonant structure by the RF field (e.g., a current induced in a current-carrying element, where the flow of current through the current-carrying element generates a magnetic field that locally influences the plasma, whether directly or indirectly).

For example, the plasma processing apparatus may include a source electrode with an upper conductive surface and a lower conductive surface (i.e., opposing conductive surfaces of an upper electrode of a CCP reactor). The RF waveguide may be bounded by the upper conductive surface and a grounded conductive surface (with a transmission material in between, such as air, but may also be a solid RF material at least partially transparent to RF frequencies), located above the upper conductive surface (e.g., the grounded conductive surface may be an interior surface of a conductive outer wall of a grounded reactor chamber). RF source power directly coupled to the source electrode (e.g., through a coaxial center feed) may cause the RF field to propagate through the RF waveguide and generate the plasma below the lower conductive surface of the source electrode. The resonant structure may be located within the RF waveguide (i.e., between the grounded conductive surface and the upper conductive surface) and be vertically aligned with a region of the upper conductive surface (such as the edge region, but of course any desired region is possible).

In some embodiments, the plasma processing apparatus may further include a dielectric spacer electrically insulating the upper and lower conductive surfaces from the grounded conductive surface. For example, the dielectric spacer may be implemented as a dielectric ring electrically insulating a source electrode from a ground wall of the plasma processing chamber. The resonant structure may include a current-carrying element that vertically overlaps with the upper conductive surface and/or the dielectric spacer. Current induced in the current-carrying element may induce localized effects directly through the dielectric spacer or indirectly through the upper conductive surface.

The resonant structure may be implemented in many geometries some of which are capacitively coupled to a grounded conductive surface (e.g., with a capacitive plate at one end of the resonant structure). The other end of the resonant structure can also be capacitively coupled to a grounded conductive surface (e.g., the same or different as the first end), or may be electrically coupled (e.g., directly connected) to a grounded conductive surface. The current-carrying element of the resonant structure may be configured to act as an inductive element (such as by including curved regions in the current-carrying element). For example, an inductive element may be a portion of the resonant structure that is proximate to the plasma, (e.g., parallel to the plasma surface), so that RF time-varying currents flowing in the current-carrying elements may produce time-varying magnetic fields that penetrate into the plasma and by doing so induce currents in the plasma. The current-carrying elements may have a variety of geometries.

Further the geometry (and potentially other factors such as the source power frequency) of the resonant structure may be selected so that the resonant structure is configured to induce electric fields in the plasma that are parallel to the plasma sheath at the interface between the plasma and the lower conductive surface (i.e., inductive localized effects). Alternatively (or even additionally in the case of different source power frequencies), the resonant structure may be configured to induce electric fields in the plasma that are perpendicular to the plasma sheath at the interface between the plasma and the lower conductive surface (i.e., capacitive localized effects).

In various embodiments, the plasma may be adjusted using the resonant structure. For example, the resonant structure is configured to interact with the RF field at a certain frequency or range of frequencies. The coupling of the resonant structure to the electric field (i.e., the potency of the localized effects) may be modified by adjusting the source power frequency relative to a peak resonant frequency of the resonant structure. Additionally, the potency of the localized effects may also depend on the properties of the resonant structure itself (including the coupling of the resonant structure to grounded surface). One example property that may be adjusted is the capacitance of the resonant structure (although this is but one example of many).

In further embodiments, a system configured to perform methods of adjusting plasma using a resonant structure may include a controller operationally coupled to at least one of an RF power source and a resonant structure. The controller has a processor and a memory (e.g., a non-transitory computer-readable medium) storing a program including instructions that, when executed by the processor, perform the method. Specifically, the method may include generating a plasma using RF source power supplied by the RF power source, inducing a current in the resonant structure that induces localized effects in the plasma using an RF field propagated through an RF waveguide by the RF source power, and adjusting the localized effects in the plasma by changing one or more of the source power frequency or the capacitance of the resonant structure.

The systems, apparatuses, and methods described herein may afford various advantages over conventional plasma processing systems. For example, as discussed above, conventional plasma reactors can produce a center-peaked plasma. The localized effects induced by embodiment resonant structures may advantageously locally enhance the plasma density in edge regions of the plasma (improving uniformity). Additionally, because the localized fields (i.e. the localized effects) are produced by resonant structures configured to only have a substantial interaction with the RF field at a specific resonant frequency (or frequencies) it may advantageously be possible to adjust the localized effects (e.g., the local electric field strength) in real time, such as on time scales of several microseconds, or even lower.

One possible benefit of the resonant structures is to provide a unique solution for enhancing radial uniformity that doesn't use an additional power source (or even couple the existing RF power source to the resonant structure; the resonant structure is source-less). Additionally, the resonant structures may have the benefit of being a low-cost solution for achieving a more uniform plasma profile and/or more control over plasma properties.

Beyond simply improving uniformity, the resonant structures may also provide additional adjustment knobs (e.g., source power frequency, resonant structure capacitance, and others) that can advantageously provide real-time (or near real-time) spatially resolved control over plasma properties, such as plasma density. For example, the improved control may allow the conversion of a center-peaked plasma (or even a substantially uniform plasma) into an edge-high plasma (i.e., a plasma with increased density at edge regions relative to center regions), which may be desirable in some applications.

Various characteristics of the plasma may also be changed, such as by increasing the coupling of the RF field to the resonant structure. In one specific example, a resonant structure may be provided over a dielectric spacer to directly induce inductive localize effects in an underlying plasma. When the coupling of the RF field to the resonant structure is weaker (e.g., because the source power frequency is farther from the peak resonance frequency of the resonant structure), the plasma may be a strongly capacitively coupled plasma since the majority of the plasma is being generated by the source electrode. If the coupling of the RF field to the resonant structure is increased (e.g., by changing the source power frequency to be closer or exactly the peak resonant frequency) then the majority of the RF power may flow through the resonant structure. In some implementations, this may advantageously generate a plasma that is strongly inductively coupled (i.e., an edge-driven ICP).

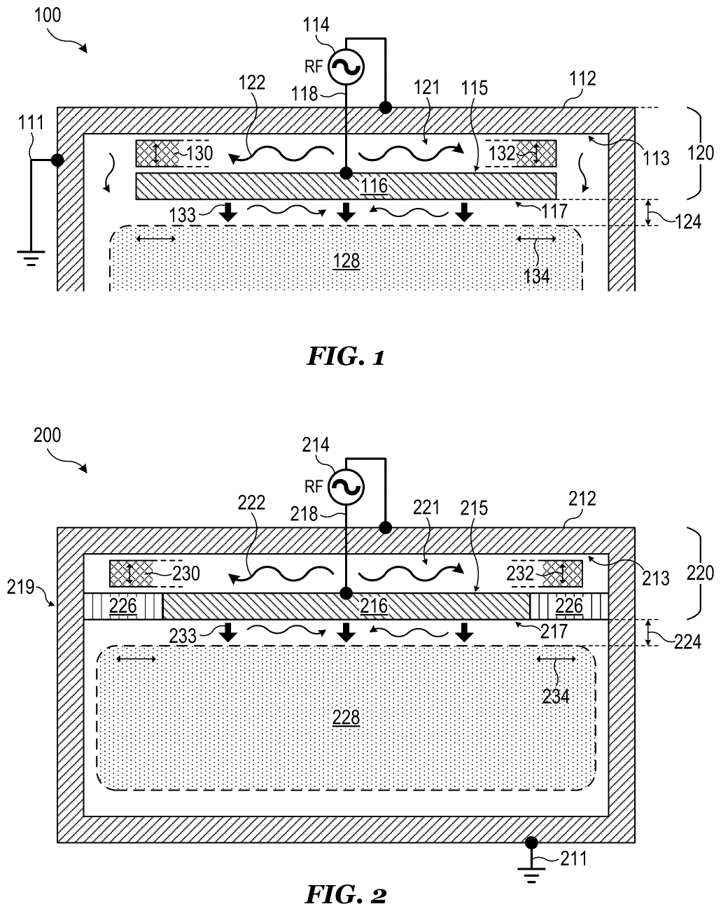

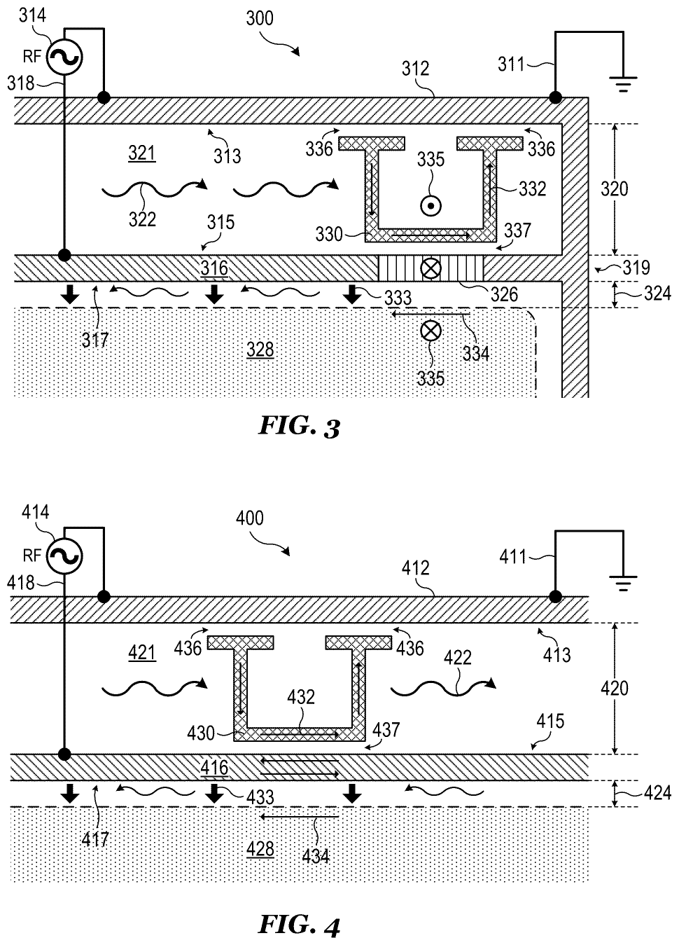

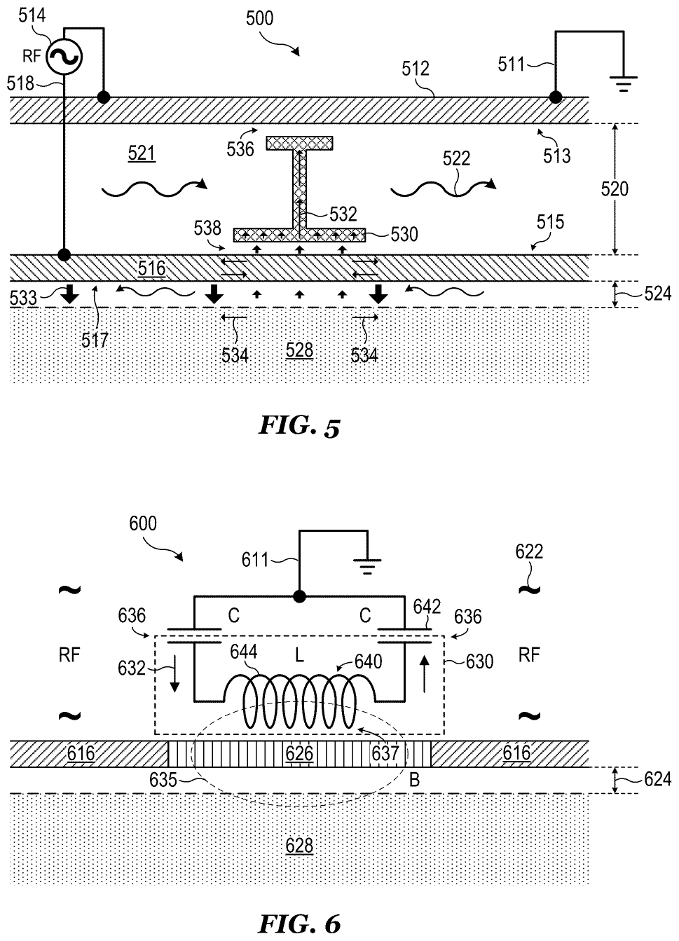

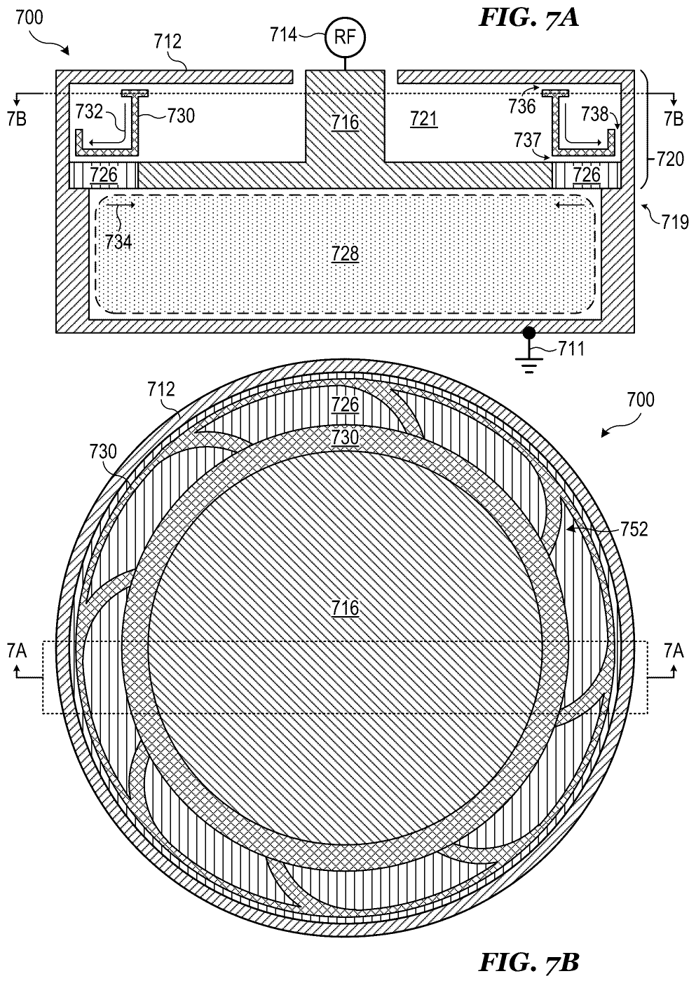

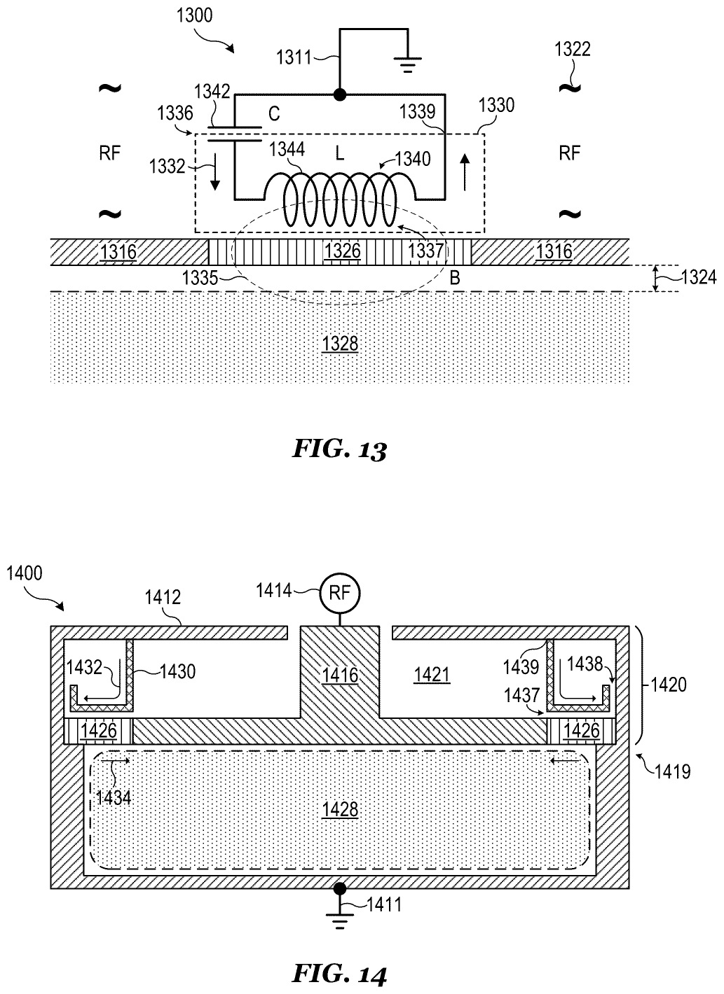

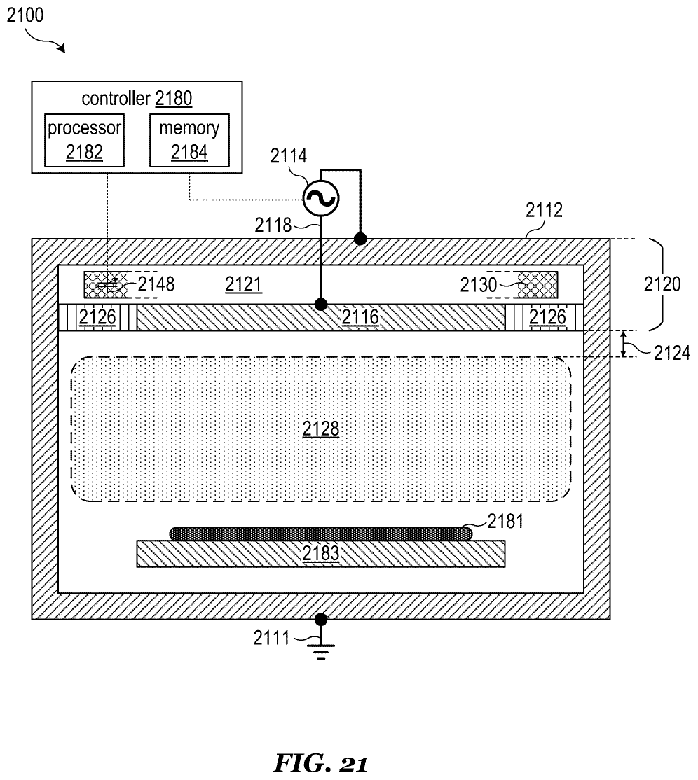

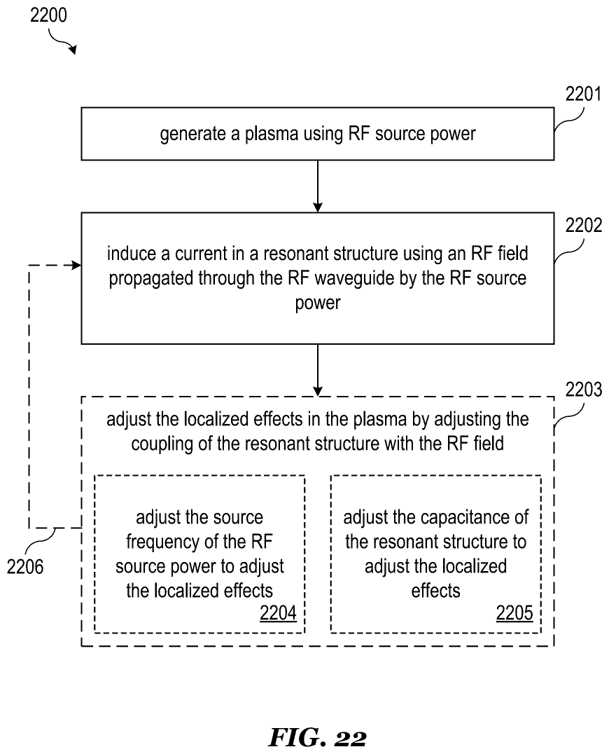

Embodiments provided below describe various systems, apparatuses, and methods for adjusting plasma, and in particular embodiments, to systems, apparatuses, and methods for adjusting plasma using a source-less resonant structure located within an RF field used to generate the plasma. The following description describes the embodiments. FIG. 1 is used to describe an example plasma processing apparatus that includes a resonant structure located in an RF field propagating between an RF driven structure and a grounded structure. Another example plasma processing apparatus that includes a source electrode separated from a grounded chamber wall by a dielectric spacer is described using FIG. 2. Three more example plasma processing apparatuses that demonstrate three types of localized effects and corresponding resonant structures are described using FIGS. 3-5. An equivalent circuit of an example resonant structure that has an inductive element as a current-carrying element that is capacitively coupled to a ground potential at both ends is described using FIG. 6. Various example plasma processing apparatuses and corresponding 3D visualizations of specific example implementations are described using FIGS. 7A-12B. Another equivalent circuit of an example resonant structure that is capacitively coupled to a ground potential at one end and directly connected to a ground potential at the other end is described using FIG. 13. Several more example plasma processing apparatuses are described using FIGS. 14-20B. FIG. 21 is used to describe an example system that may include the plasma processing apparatuses and resonant structures and perform the methods herein described. FIG. 22 is used to describe an example method of adjusting plasma using a resonant structure.

FIG. 1 illustrates an example plasma processing apparatus that includes a resonant structure disposed within an RF field propagating between an RF driven structure and a grounded structure that together from an RF waveguide in accordance with embodiments of the invention.

Referring to FIG. 1, a plasma processing apparatus 100 includes a grounded structure 112 electrically coupled to a ground potential 111 (such as a plasma processing chamber, reactor chamber, etc., but may also be implemented using conductive material(s) that are separate from a chamber wall, for example). The plasma processing apparatus 100 may be any suitable type of plasma processing apparatus, such as a plasma etching apparatus (e.g., a reactive-ion etching (RIE) reactor), such as a CCP reactor, an ICP reactor, or a plasma deposition apparatus, such as a plasma-enhanced chemical vapor deposition (PE-CVD) apparatus, PE-ALD apparatus, plasma-enhanced molecular deposition (PE-MLD) apparatus, and others. An RF power source 114 is coupled to an RF driven structure 116 (e.g., a conductive material, such as a source electrode) and is configured to supply RF source power 118 to the RF driven structure 116 to generate a plasma 128 (e.g., within a plasma processing chamber). The plasma 128 is a CCP plasma in one embodiment, but may also be a an ICP, an SWP, and others provided that generating such a plasma is consistent with the various structural configurations of the plasma processing apparatus 100 described herein.

The RF driven structure 116 has an upper conductive surface 115 and a lower conductive surface 117 (either of which may be coated with another material, including being coated with a dielectric material). An RF waveguide 120 exists between (i.e., is formed by) the upper conductive surface 115 and an inner grounded conductive surface 113 of the grounded structure 112 (e.g., a chamber wall, which is configured to function as a side of the RF waveguide 120). That is, the when the RF source power 118 is supplied to the RF driven structure 116, an RF field 122 is generated in the RF waveguide 120 and propagates through a transmission material 121 (e.g., air, or any other RF at least partially RF transparent material, such as a solid dielectric material) of the RF waveguide 120. As shown, the RF field 122 travels from the RF feed point of the RF source power 118 (e.g., a coaxial feed) outward and is then guided around the RF driven structure 116 and inward along the interface of the bulk plasma and a plasma sheath 124 between the plasma 128 and the lower conductive surface 117 of the RF driven structure 116. When the RF source power 118 is turned on to generate the plasma 128, a plasma current 133 (e.g., a displacement current as shown here, as in a CCP plasma) flows from the RF driven structure 116 into the plasma 128. Thus, the electric field in the plasma sheath 124 may be perpendicular to the lateral extent of the plasma sheath 124 of the plasma 128 along the lower conductive surface 117.

A resonant structure 130 is positioned in the RF waveguide 120 (here, shown as overlapping the RF driven structure 116, but which may also be positioned differently within the RF waveguide 120). The resonant structure 130 is configured to interact with the RF field 122 at a specific resonant frequency (or range or frequencies) so that the RF field 122 induces a resonant current 132 in the resonant structure 130. The resonant current 132 interacts with the plasma 128 (either directly or indirectly, such as by inducing fields (i.e. currents) in the RF driven structure 116) to induce localized effects 134 (i.e. localized fields) in the plasma 128. As will be subsequently discussed in more detail, the localized effects 134 may induce fields (and currents) with directional components both parallel to the plasma sheath 124 (inductive localized effects) and perpendicular to the plasma sheath 124 (capacitive localized effects) depending on operating parameters, geometry, and position of the resonant structure 130 within the RF waveguide 120.

The RF source power 118 is supplied to the RF driven structure 116 at a desired operating frequency (i.e., the frequency of the source power; the “main driving frequency”; a source power frequency), which may be in the RF portion of the electromagnetic spectrum (e.g., all electromagnetic radiation up to about 300 MHz, but often used to refer to frequencies up to 300 GHz (1 mm wavelength)). For example, microwaves may be considered a subset of radio waves with frequencies between 300 MHz and 300 GHz. In various embodiments, that source power frequency is greater than about 3 MHz. In some embodiments, the source power frequency is in the HF (high frequency) portion of the electromagnetic spectrum between about 3 MHz and about 30 MHz. In other embodiments, the source power frequency is in the VHF (very high frequency) portion of the electromagnetic spectrum, and is about 200 MHz in one embodiment. Of course, any desired VHF frequency is possible for these embodiments, such as about 400 MHZ, and others. In other embodiments, the source power frequency is in the microwave portion of the electromagnetic spectrum between about 300 MHz and about 300 GHz, and is about 700 MHz in one embodiment.

The characteristics of the RF field 122 within the RF waveguide 120 depend on the source power frequency. For example, as already mentioned, standing waves form in the central region of the RF driven structure 116 (i.e., a center-peaked plasma is formed by the standing waves), and are worsened (e.g., enlarged) when the source power frequency is higher. Microwaves may have short enough wavelengths to produce secondary peaks (higher order standing waves) that have additional electric field antinodes vertically aligned with intermediate regions of the RF driven structure 116. Additionally, higher frequencies may introduce azimuthal inhomogeneity (in contrast with substantial azimuthal symmetry at lower frequencies). The overall effect of the standing waves generated by the RF field 122 propagating through the RF waveguide 120 is to decrease the spatial uniformity (e.g., the plasma profile) of various characteristics of the plasma 128, such as ion, electron, and radical density, temperature, and flux (e.g., at a substrate being processed), plasma current.

In some cases, the type of plasma process may affect the choice of source power frequency. For example, etching processes may use relatively lower frequencies to increase the ion energy while deposition processes may use relatively higher frequencies to have a lower ion energy, and optimize the ion and radical fluxes. Other factors may also increase the scale of the non-uniformities in the plasma, such as increased source power or the plasma chemistry.

In many applications, RF source power with a source power frequency in the VHF range may be desirable. For example, VHF plasma may be lower cost, have easier maintenance, and higher manufacturability than MW plasma. VHF plasma may also be able to provide optimum ion energy (Eᵢ), high ion flux (Tᵢ), and high radical flux (Tₙ), which may be beneficial in a variety of plasma processes, such as plasma deposition processes (e.g., PE-ALD). The improved plasma parameters may advantageously enable high quality films at lower temperatures, for example.

The interaction of the resonant structure 130 with the RF field 122 is based on the geometry of the resonant structure 130, as well as other factors such as circuit components or properties such as capacitance, inductance, and impedance. Additionally, the magnitude of the resonant current 132 may be influenced by the coupling of the resonant structure 130 with the surrounding conductive materials, such as the RF driven structure 116, the grounded structure 112, and others. The resonant frequency of the resonant structure 130 may be a band of frequencies (i.e., a range of frequencies within which the induced localized effects 134 in the plasma 128 meet desired criteria). Such a band of frequencies (or frequency window) may then have a peak resonant frequency at which the localized effects 134 are maximized. Since the response of the resonant structure 130 depends on the source power frequency (i.e. correlated to the frequency of the RF field 122), the source power frequency may be varied within the frequency window to alter the potency of the resonant structure 130.

The resonant structure 130 is a source-less resonant structure. That is, the resonant structure 130 is disconnected from the RF power source 114 and is not supplied with alternative RF power (i.e., the resonant structure 130 does not produce an electromagnetic field but is instead driven by an appropriate, existing electromagnetic field). In some embodiments, the resonant structure 130 is electrically floating (i.e., entirely electrically insulated from RF sources and ground potentials). In other embodiments, the resonant structure 130 may be grounded, such as electrically coupled to the ground potential 111 through the grounded structure 112, for example. One example of such a configuration is to capacitively couple one end of a current-carrying element of the resonant structure 130 to a grounded surface (i.e., electrically insulated from the grounded surface, but still capacitively coupled through the overlap of conductors (capacitive plates) separated by a dielectric) and another end electrically coupled to a grounded surface (e.g., directly connected).

The resonant structure 130 may be implemented as an entirely passive circuit, or may include active elements related to adjusting the potency of the resonant structure 130 in the RF field 122 (but not, for instance, to provide additional source power for plasma generation). Specifically, while the resonant structure 130 may directly generate localized plasma in the plasma 128, it does so through interaction (i.e., coupling) with the RF field 122 and not from a separate power source.

The resonant structure 130 may be an electrically continuous structure or may have multiple electrically separate structures. In various embodiments, the resonant structure 130 may have some degree of azimuthal symmetry about a central vertical axis of the RF driven structure 116 (e.g., when included in a cylindrical plasma processing chamber), such as forming a ring at some distance from the central region of the RF driven structure 116. Any degree of azimuthal symmetry is possible, such as 4-fold (rotational invariance for 90° rotations), 8-fold (rotational invariance for 45° rotations), and others. Additional resonant structure 130 may also be included, (e.g., multiple rings) or the resonant structure 130 may be a single electrically continuous structure with resonant features at different distances from the center. Additionally, multiple resonant features of the resonant structure 130 at the same (or similar) distances from the central region may be electrically separate (i.e., forming multiple resonant segments, each inducing a respective localized effect in the plasma 128). Coupling (e.g., via capacitive plates) may be made to any grounded surface, including the inner grounded conductive surface 113 as well as inner grounded surfaces of a sidewall.

FIG. 2 illustrates an example plasma processing apparatus that includes resonant structure disposed within an RF field propagating through an RF waveguide and a source electrode separated from a grounded chamber wall by a dielectric spacer in accordance with embodiments of the invention. The plasma processing apparatus of FIG. 2 may be a specific implementation of other plasma processing apparatuses described herein such as the plasma processing apparatus of FIG. 1, for example. Similarly labeled elements may be as previously described.

Referring to FIG. 2, a plasma processing apparatus 200 includes a grounded structure 212 (shown here as a chamber, such as a plasma processing chamber) coupled to a ground potential 211. An RF power source 214 is coupled to a source electrode 216 (e.g., an upper source electrode; a specific implementation of an RF driven structure) and is configured to supply RF source power 218 to the source electrode 216 to generate a plasma 228 in the chamber (the grounded structure 212). The source electrode 216 has an upper conductive surface 215 and a lower conductive surface 217. An RF waveguide 220 exists between (i.e., is formed by) the upper conductive surface 215 and an inner grounded conductive surface 213 of the grounded structure 212. A dielectric spacer 226 (e.g., a dielectric ring) electrically insulates the source electrode 216 from a grounded chamber wall 219 of the grounded structure 212. A resonant structure 230 is positioned in a RF waveguide 220 vertically overlapping at least one of the source electrode 216 and the dielectric spacer 226.

It should be noted that here and in the following a convention has been adopted for brevity and clarity wherein elements adhering to the pattern [x30] where ‘x’ is the figure number may be related implementations of a resonant structure in various embodiments. For example, the resonant structure 230 may be similar to the resonant structure 130 except as otherwise stated. An analogous convention has also been adopted for other elements as made clear by the use of similar terms in conjunction with the aforementioned numbering system.

When the RF source power 218 is supplied to the source electrode 216, an RF field 222 is generated in the RF waveguide 220 and propagates through a transmission material 221 of the RF waveguide 220. A plasma sheath 224 extends laterally along the lower conductive surface 217 perpendicular to electric field lines within the sheath (e.g., causing a displacement current (a plasma current 233) from the source electrode 216 to the plasma 228). The RF field 222 induces a resonant current 232 in the resonant structure 230 that in turn induces localized effects 234 in the plasma 228.

As referenced in the foregoing, the positioning of the resonant structure 230 within the RF waveguide 220 may vary. For example, the resonant structure 230 may vertically overlap the dielectric spacer 226 (and thereby directly influence the plasma 228 through the dielectric spacer 226 causing direct localized effects). The resonant structure 230 may also vertically overlap the source electrode 216 (e.g., an upper source electrode, such as a UEL) and directly influence fields in the source electrode 216 that indirectly influence the plasma 228 causing indirect localized effects. Of course, the resonant structure 230 may also vertically overlap some combination of the two, with varying degrees, and may even be configured to be adjusted relative to the dielectric spacer 226 and the source electrode 216 to alter the character of the localized effects 234.

In various embodiments, the resonant structure 230 is located at edge regions of the plasma (such as when it is desirable to increase the local density of the plasma 228 relative to the plasma density in the center in order to flatten a center-peaked plasma or even generate an edge-high plasma). The resonant structure 230 or additional resonant structure may be included at any desirable region, depending on the desired localized effects in the plasma for a given application.

FIG. 3 illustrates an example plasma processing apparatus that includes resonant structure disposed within an RF field propagating through an RF waveguide where the resonant structure is configured to directly induce localized effects in a plasma (e.g., directly induce heating in plasma at localized regions beneath a dielectric material) in accordance with embodiments of the invention. The plasma processing apparatus of FIG. 3 may be a specific implementation of other plasma processing apparatuses described herein such as the plasma processing apparatus of FIG. 1, for example. Similarly labeled elements may be as previously described.

Referring to FIG. 3, a plasma processing apparatus 300 includes a grounded structure 312 coupled to a ground potential 311. An RF power source 314 is coupled to a source electrode 316 and is configured to supply RF source power 318 to the source electrode 316 to generate a plasma 328. The source electrode 316 has an upper conductive surface 315 and a lower conductive surface 317. An RF waveguide 320 exists between (i.e., is formed by) the upper conductive surface 315 and a grounded conductive surface 313 of the grounded structure 312. A dielectric spacer 326 (e.g., a dielectric ring) electrically insulates the source electrode 316 from a grounded chamber wall 319 of the grounded structure 312. A U-shaped resonant structure 330 is positioned in the RF waveguide 320 vertically overlapping at least one of the source electrode 316 and the dielectric spacer 326. The “U-shape” of the U-shaped resonant structure 330 is but one specific example of many general geometries which may be appropriate to induce a current, many of which are described elsewhere.

The RF source power 318 generates an RF field 322 propagating through a transmission material 321 of the RF waveguide 320. A plasma sheath 324 extends laterally along the lower conductive surface 317 perpendicular to electric field lines within the sheath (e.g., causing a displacement current (a plasma current 333) from the source electrode 316 to the plasma 328). The RF field 322 induces a resonant current 332 in the U-shaped resonant structure 330 that in turn induces direct localized effects 334 in the plasma 328.

The shape of the U-shaped resonant structure 330 allows for both ends of a current-carrying element of the U-shaped resonant structure 330 to have a capacitive coupling 336 (e.g., via capacitive plates) with an upper grounded surface (the grounded conductive surface 313) and for the resonant current 332 to flow from one end of the current-carrying element to the other through a lower segment of the U-shaped resonant structure 330 that has an inductive coupling 337 with the plasma 328 resulting in an induced magnetic field 335 in the plasma 328 causing the direct localized effects 334 (e.g., localized currents, fields, etc.) In this case, the induced fields are substantially parallel to the extent of the plasma sheath 324 and may be considered inductive localized effects, though direct capacitive localized effects are also possible.

FIG. 4 illustrates an example plasma processing apparatus that includes resonant structure disposed within an RF field propagating through an RF waveguide where the resonant structure is configured to indirectly induce inductive localized effects in a plasma (e.g., using induced current to indirectly cause localized fields in a plasma region) in accordance with embodiments of the invention. The plasma processing apparatus of FIG. 4 may be a specific implementation of other plasma processing apparatuses described herein such as the plasma processing apparatus of FIG. 1, for example. Similarly labeled elements may be as previously described.

Referring to FIG. 4, a plasma processing apparatus 400 includes a grounded structure 412 coupled to a ground potential 411. An RF power source 414 is coupled to a source electrode 416 and is configured to supply RF source power 418 to the source electrode 416 to generate a plasma 428. The source electrode 416 has an upper conductive surface 415 and a lower conductive surface 417. An RF waveguide 420 exists between (i.e., is formed by) the upper conductive surface 415 and a grounded conductive surface 413 of the grounded structure 412. A U-shaped resonant structure 430 is positioned in the RF waveguide 420 vertically overlapping the source electrode 416.

The RF source power 418 generates an RF field 422 propagating through a transmission material 421 of the RF waveguide 420. A plasma sheath 424 extends laterally along the lower conductive surface 417 perpendicular to electric field lines within the sheath (e.g., causing a displacement current (a plasma current 433) from the source electrode 416 to the plasma 428). The RF field 422 induces a resonant current 432 in the U-shaped resonant structure 430 that in turn induces indirect localized effects 434 in the plasma 428.

Similar to the U-shaped resonant structure 330, the shape of the U-shaped resonant structure 430 also allows for both ends of a current-carrying element of the U-shaped resonant structure 430 to have a capacitive coupling 436 with the grounded conductive surface 413 and for the resonant current 432 that has an inductive coupling 437 with the source electrode 416 and induces a magnetic field. However, in contrast to the direct configuration of U-shaped resonant structure 330, the U-shaped resonant structure 430 directly induces localized effects in the source electrode 416 and only indirectly induces the indirect localized effects 434 in the plasma 428. Again in this example, the induced fields are substantially parallel to the extent of the plasma sheath 424 and may be considered inductive localized effects.

FIG. 5 illustrates an example plasma processing apparatus that includes resonant structure disposed within an RF field propagating through an RF waveguide where the resonant structure is configured to indirectly induce capacitive localized effects in a plasma (e.g., using induced displacement current to indirectly cause localized fields in a plasma region) in accordance with embodiments of the invention. The plasma processing apparatus of FIG. 5 may be a specific implementation of other plasma processing apparatuses described herein such as the plasma processing apparatus of FIG. 1, for example. Similarly labeled elements may be as previously described.

Referring to FIG. 5, a plasma processing apparatus 500 includes a grounded structure 512 coupled to a ground potential 511. An RF power source 514 is coupled to a source electrode 516 and is configured to supply RF source power 518 to the source electrode 516 to generate a plasma 528. The source electrode 516 has an upper conductive surface 515 and a lower conductive surface 517. An RF waveguide 520 exists between (i.e., is formed by) the upper conductive surface 515 and a grounded conductive surface 513 of the grounded structure 512. A dielectric spacer 526 (e.g., a dielectric ring) electrically insulates the source electrode 516 from an inner grounded chamber wall 513 of the grounded structure 512. An I-shaped resonant structure 530 is positioned in the RF waveguide 520 vertically overlapping at least one of the source electrode 516 and the dielectric spacer 526. The “I-shape” of the I-shaped resonant structure 530 is but one specific example of many general geometries which may be appropriate to induce a current, many of which are described elsewhere.

The RF source power 518 generates an RF field 522 propagating through a transmission material 521 of the RF waveguide 520. A plasma sheath 524 extends laterally along the lower conductive surface 517 perpendicular to electric field lines within the sheath (e.g., causing a displacement current (a plasma current 533) from the source electrode 516 to the plasma 528). The RF field 522 induces a resonant current 532 in the I-shaped resonant structure 530 that in turn induces indirect localized effects 534 in the plasma 528.

The shape of the I-shaped resonant structure 530 allows for one end of a current-carrying element of the I-shaped resonant structure 530 to have a top capacitive coupling 536 with the grounded conductive surface 513 and a bottom capacitive coupling 538 with the source electrode 516. A resonant current 532 is induced in a vertical segment of the RF waveguide 520 which causes a localized displacement current from the I-shaped resonant structure 530 through the I-shaped resonant structure 530 and to the plasma 528. This results in an indirectly induced electric field in the plasma 528 that a magnetic field that is substantially perpendicular to the extent of the plasma sheath 524. For this reason, the indirect localized effects 534 may be considered to be capacitive localized effects.

FIG. 6 illustrates an equivalent circuit of an example resonant structure that includes a current-carrying element capacitively coupled to a grounded surface on both ends in accordance with embodiments of the invention. The example resonant structure of FIG. 6 may be a specific implementation of other resonant structures described herein such as the resonant structure of FIG. 3, for example. Similarly labeled elements may be as previously described.

Referring to FIG. 6, an equivalent circuit 600 of a resonant structure 630 includes a current-carrying element 640 electrically coupled between two capacitive elements 642. The capacitive elements 642 each have a capacitive coupling 636 with a ground potential (e.g., the ground potential 611, but could also be separate ground potentials). The current-carrying element 640 may also include an inductive element 644, such as curved portions of the current-carrying element 640 that are configured to increase the inductance of the current-carrying element 640. An RF field 622 induces a resonant current 632 in the current-carrying element 640 that induces an induced magnetic field 635. The current-carrying element 640 has an inductive coupling 637 either directly with a plasma 628 through a dielectric spacer 626 (as shown) or indirectly with a conductive material 616, such as source electrode. The plasma 628 has a plasma sheath 624 extending laterally along a surface opposing the resonant structure 630 (e.g., a lower surface of a dielectric like the dielectric spacer 626 or a lower surface of a conductive surface like a source electrode).

FIGS. 7A and 7B illustrate an example plasma processing apparatus that includes an L-shaped resonant structure where FIG. 7A shows a side view and FIG. 7B shows a corresponding overhead view in accordance with embodiments of the invention. The plasma processing apparatus of FIGS. 7A and 7B may be a specific implementation of other plasma processing apparatuses described herein such as the plasma processing apparatus of FIG. 1, for example. Similarly labeled elements may be as previously described.

Referring to FIGS. 7A and 7B, a plasma processing apparatus 700 includes a ground potential 711 electrically coupled to a grounded structure 712 and an RF power source 714 electrically coupled to a source electrode 716 configured to generate a plasma 728 using an RF field propagating through a transmission material 721 of an RF waveguide 720 formed by the source electrode 716 and the grounded structure 712. The grounded structure 712 is implemented as a plasma processing chamber and a dielectric ring 726 electrically insulates the source electrode 716 from a grounded chamber wall 719.

Similar to the U-shaped resonant structure 330 of FIG. 3, an L-shaped resonant structure 730 is included within the RF waveguide 720 vertically overlapping the dielectric ring 726. However, in contrast to the U-shaped resonant structure 330, which had two plates capacitively coupled to an upper grounded surface, the L-shaped resonant structure 730 has a top capacitive coupling 736 to an upper surface of the grounded structure 712 as well as a side capacitive coupling 738 with the grounded chamber wall 719. The source electrode 716 generates an RF field in the RF waveguide 720 that induces a resonant current 732 in the L-shaped resonant structure 730. The resonant current 732 induces direct localized effects 734 through an inductive coupling 737 through the dielectric ring 726.

As mentioned in the foregoing, the resonant structures may include curved current paths (such as non-radial components, but may also be straight, “S-shaped”, or more complicated, so long as the resonant structure includes current paths that are substantially parallel to the plasma interface) as part of the current-carrying element that are configured to act as inductive elements. In this specific example, the L-shaped resonant structure 730 is implemented as a single electrically continuous structure that has multiple spiral segments 752, each directly connected to both an upper capacitive plate (a conductive ring) and a side capacitive plate (a conductive band).

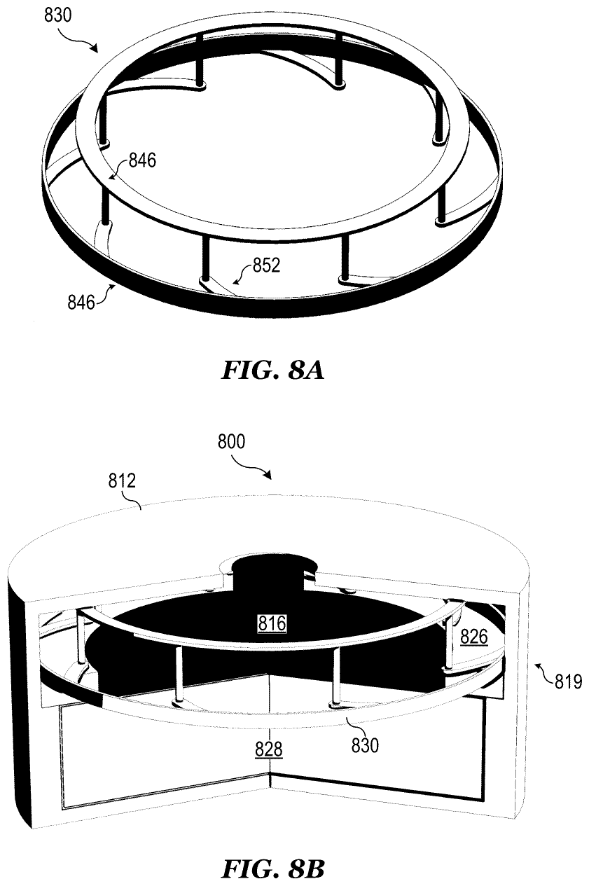

FIGS. 8A and 8B illustrate 3D views of a specific implementation of an example plasma processing apparatus that includes an L-shaped resonant structure where FIG. 8A shows the resonant structure and FIG. 8B shows a cutaway view of the plasma processing apparatus in accordance with embodiments of the invention. Similarly labeled elements may be as previously described.

Referring to FIGS. 8A and 8B, a plasma processing apparatus 800 includes an L-shaped resonant structure 830 within a plasma processing chamber 812 between a source electrode 816 configured to generate a plasma 828 and a grounded upper wall of the plasma processing chamber 812. The L-shaped resonant structure 830 has eight spiral segments 852 that are vertically overlapping a dielectric ring 826 electrically insulating the source electrode 816 from the grounded chamber wall 819. The spiral segments 852 are each electrically coupled to two capacitive plates 846, one at the grounded upper wall of the plasma processing chamber 812 and one at the grounded chamber wall 819.

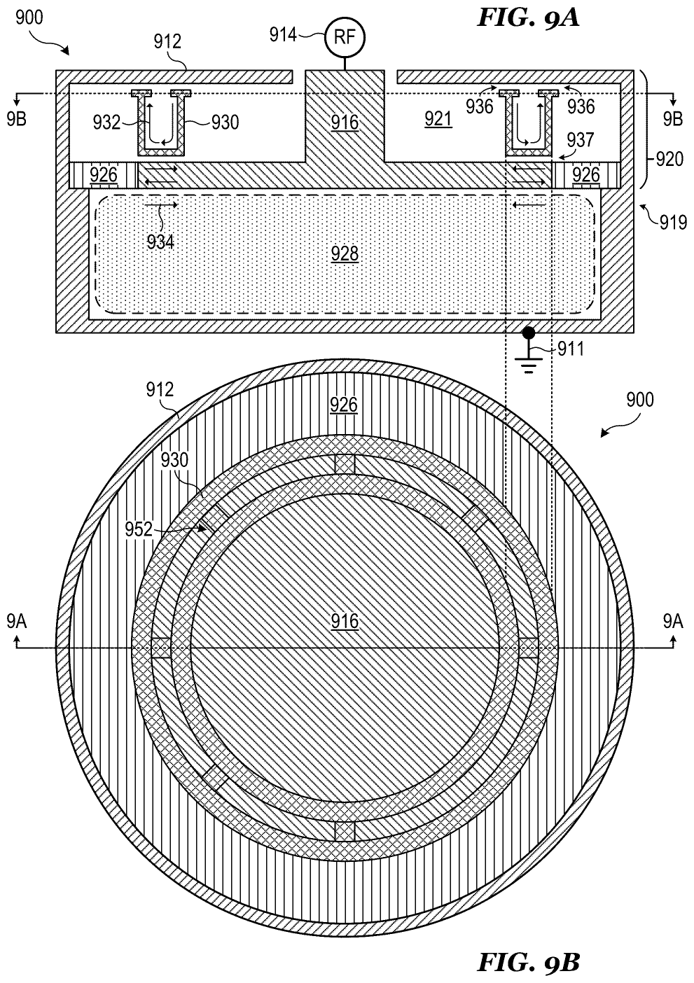

FIGS. 9A and 9B illustrate an example plasma processing apparatus that includes a U-shaped resonant structure where FIG. 9A shows a side view and FIG. 9B shows a corresponding overhead view in accordance with embodiments of the invention. The plasma processing apparatus of FIGS. 9A and 9B may be a specific implementation of other plasma processing apparatuses described herein such as the plasma processing apparatus of FIG. 1, for example. Similarly labeled elements may be as previously described.

Referring to FIGS. 9A and 9B, a plasma processing apparatus 900 includes a ground potential 911 electrically coupled to a grounded structure 912 and an RF power source 914 electrically coupled to a source electrode 916 configured to generate a plasma 928 using an RF field propagating through a transmission material 921 of an RF waveguide 920 formed by the source electrode 916 and the grounded structure 912. The grounded structure 912 is implemented as a plasma processing chamber and a dielectric ring 926 electrically insulates the source electrode 916 from a grounded chamber wall 919.

Now in analogy with the U-shaped resonant structure 430 of FIG. 4, a U-shaped resonant structure 930 is included within the RF waveguide 920 that vertically overlaps an edge region of the source electrode 916. Both ends of the U-shaped resonant structure 930 have a capacitive coupling 936 with an upper grounded surface of the grounded structure 912. The source electrode 916 generates an RF field in the RF waveguide 920 that induces a resonant current 932 in the U-shaped resonant structure 930. The resonant current 932 flowing through a lower segment of a current-carrying element of the U-shaped resonant structure 930 has an inductive coupling 937 with the source electrode 916 (direct inductive coupling) and an indirect inductive coupling with the plasma 928 so as to induce indirect localized effects 934.

In contrast to the curved current-carrying element of the spiral segments 752 of the L-shaped resonant structure 730, the current-carrying element of the U-shaped resonant structure 930 includes multiple straight segments 952. Of course, these configurations are merely provided as examples and the spiral segments are not required to correspond with L-shaped resonant structures. Nor are straight segments required to correspond with U-shaped resonant structures. Rather, the specific geometry of the resonant structures is highly flexible and the specific details will depend on the specific details of a given application.

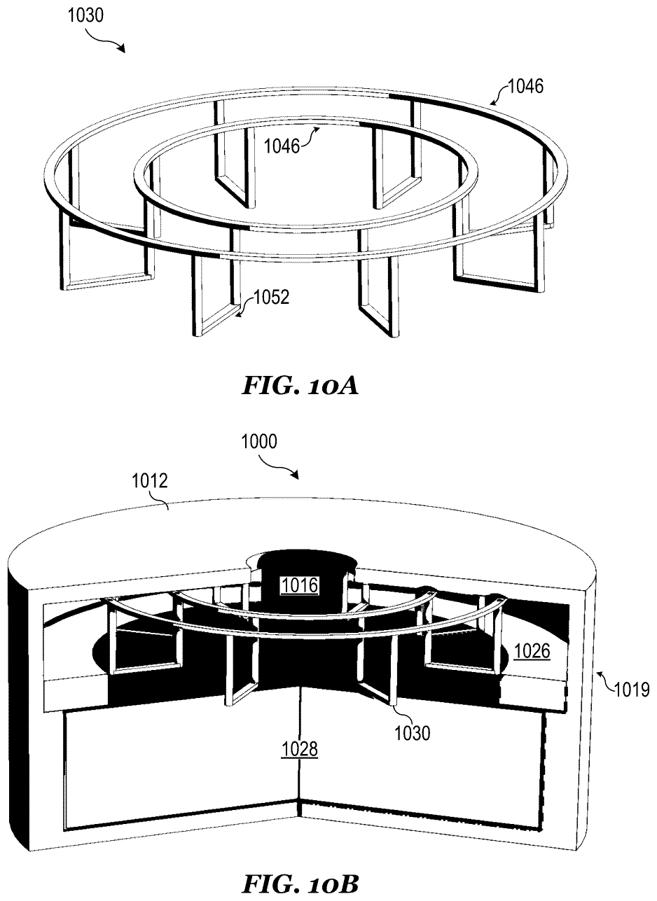

FIGS. 10A and 10B illustrate 3D views of a specific implementation of an example plasma processing apparatus that includes a U-shaped resonant structure where FIG. 10A shows the resonant structure and FIG. 10B shows a cutaway view of the plasma processing apparatus in accordance with embodiments of the invention. Similarly labeled elements may be as previously described.

Referring to FIGS. 10A and 10B, a plasma processing apparatus 1000 includes a U-shaped resonant structure 1030 within a plasma processing chamber 1012 between a source electrode 1016 configured to generate a plasma 1028 and a grounded upper wall of the plasma processing chamber 1012. The U-shaped resonant structure 1030 has eight straight segments 1052 that are vertically overlapping the source electrode 1016, which is insulated from the grounded chamber wall 1019 by a dielectric ring 1026. The straight segments 1052 are each electrically coupled to two concentric capacitive plates 1046, both at the grounded upper wall of the plasma processing chamber 1012.

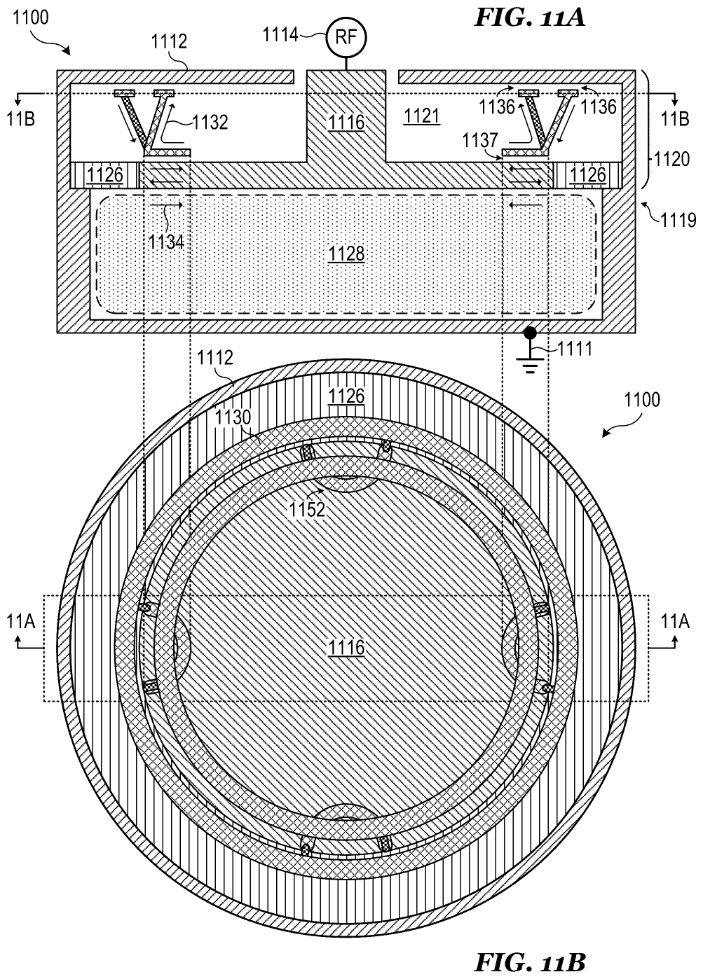

FIGS. 11A and 11B illustrate an example plasma processing apparatus that includes a horseshoe resonant structure where FIG. 11A shows a side view and FIG. 11B shows a corresponding overhead view in accordance with embodiments of the invention. The plasma processing apparatus of FIGS. 11A and 11B may be a specific implementation of other plasma processing apparatuses described herein such as the plasma processing apparatus of FIG. 1, for example. Similarly labeled elements may be as previously described.

Referring to FIGS. 11A and 11B, a plasma processing apparatus 1100 includes a ground potential 1111 electrically coupled to a grounded structure 1112 and an RF power source 1114 electrically coupled to a source electrode 1116 configured to generate a plasma 1128 using an RF field propagating through a transmission material 1121 of an RF waveguide 1120 formed by the source electrode 1116 and the grounded structure 1112. The grounded structure 1112 is implemented as a plasma processing chamber and a dielectric ring 1126 electrically insulates the source electrode 1116 from a grounded chamber wall 1119.

Also similar to the U-shaped resonant structure 430 of FIG. 4, a horseshoe resonant structure 1130 is included within the RF waveguide 1120 that vertically overlaps an edge region of the source electrode 1116. The horseshoe resonant structure 1130 has both ends with a capacitive coupling 1136 to an upper grounded surface of the grounded structure 1112, but in contrast so the other example U-shaped resonant structures, the horseshoe resonant structure 1130 is turned 90 degrees and a horseshoe segment 1152 (e.g., an inductive element) is included as part of the current-carrying element. The source electrode 1116 generates an RF field in the RF waveguide 1120 that induces a resonant current 1132 in the horseshoe resonant structure 1130. The resonant current 1132 flowing through a lower segment of a current-carrying element of the horseshoe resonant structure 1130 has an inductive coupling 1137 with the source electrode 1116 (direct inductive coupling) and an indirect inductive coupling with the plasma 1128 so as to induce indirect localized effects 1134.

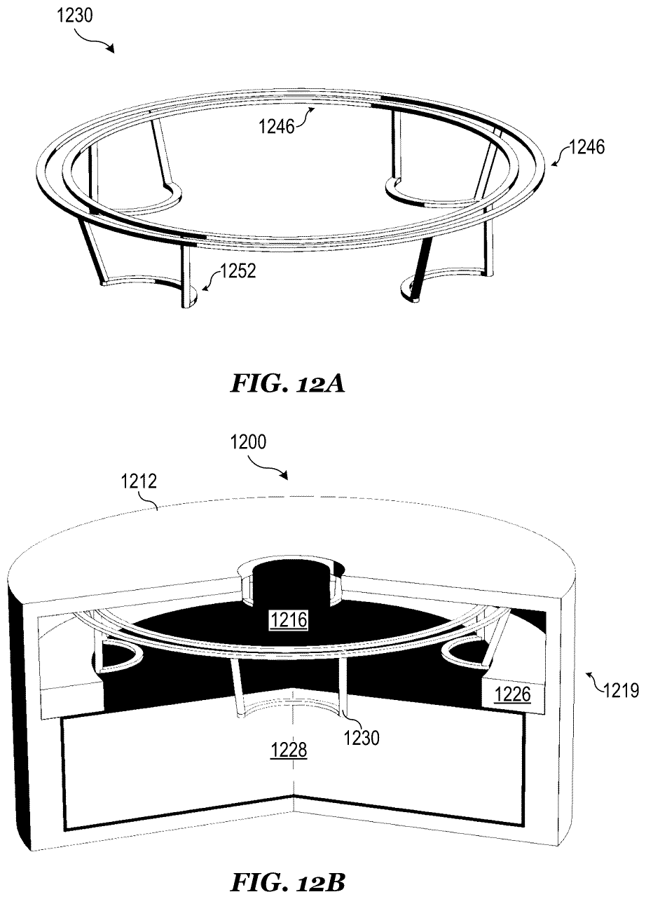

FIGS. 12A and 12B illustrate 3D views of a specific implementation of an example plasma processing apparatus that includes a horseshoe resonant structure where FIG. 12A shows the resonant structure and FIG. 12B shows a cutaway view of the plasma processing apparatus in accordance with embodiments of the invention. Similarly labeled elements may be as previously described.

Referring to FIGS. 12A and 12B, a plasma processing apparatus 1200 includes a horseshoe resonant structure 1230 within a plasma processing chamber 1212 between a source electrode 1216 configured to generate a plasma 1228 and a grounded upper wall of the plasma processing chamber 1212. The horseshoe resonant structure 1230 has eight horseshoe segments 1252 that are vertically overlapping a dielectric ring 1226 electrically insulating the source electrode 1216 from the grounded chamber wall 1219. The horseshoe segments 1252 are each electrically coupled to two concentric capacitive plates 1246, both at the grounded upper wall of the plasma processing chamber 1212.

FIG. 13 illustrates an equivalent circuit of an example resonant structure that includes a current-carrying element capacitively coupled to a grounded surface on one end and electrically coupled to a grounded surface on the other end in accordance with embodiments of the invention. The example resonant structure of FIG. 13 may be a specific implementation of other resonant structures described herein such as the resonant structure of FIG. 14, for example. Similarly labeled elements may be as previously described.

Referring to FIG. 13, an equivalent circuit 1300 of a resonant structure 1330 is similar to the equivalent circuit 600 of FIG. 6 except that only one end of a current-carrying element 1340 electrically coupled is coupled to a capacitive element 1342 and has a capacitive coupling 1336 with a ground potential 1311. The other end of the current-carrying element 1340 is electrically coupled to the ground potential 1311 (e.g., direct electrical coupling 1339). As before, an inductive element 1344 may also be included. An RF field 1322 induces a resonant current 1332 in the current-carrying element 1340 that induces an induced magnetic field 1335. The current-carrying element 1340 has an inductive coupling 1337 either directly with a plasma 1328 through a dielectric spacer 1326 (as shown) or indirectly with a conductive material 1316, such as source electrode. The plasma 1328 has a plasma sheath 1324 extending laterally along a surface opposing the resonant structure 1330 (e.g., a lower surface of a dielectric like the dielectric spacer 1326 or a lower surface of a conductive surface like a source electrode).

FIG. 14 illustrates a side view of an example plasma processing apparatus that includes an L-shaped resonant structure directly connected to a grounded surface of a plasma processing chamber in accordance with embodiments of the invention. The plasma processing apparatus of FIG. 14 may be a specific implementation of other plasma processing apparatuses described herein such as the plasma processing apparatus of FIG. 1, for example. Similarly labeled elements may be as previously described.

Referring to FIG. 14, a plasma processing apparatus 1400 includes a ground potential 1411 electrically coupled to a grounded structure 1412 and an RF power source 1414 electrically coupled to a source electrode 1416 configured to generate a plasma 1428 using an RF field propagating through a transmission material 1421 of an RF waveguide 1420 formed by the source electrode 1416 and the grounded structure 1412. The grounded structure 1412 is implemented as a plasma processing chamber and a dielectric ring 1426 electrically insulates the source electrode 1416 from a grounded chamber wall 1419.

An L-shaped resonant structure 1430 included within the RF waveguide 1420 vertically overlaps the dielectric ring 1426 and is the same as the L-shaped resonant structure 730 except that one end of the current-carrying element of the L-shaped resonant structure 1430 is electrically coupled (e.g., directly coupled forming a direct electrical coupling 1439) to a grounded surface of the grounded structure 1412 (here, the upper end of the L-shaped resonant structure 1430 is connected to an upper surface of the grounded structure 1412, but of course this isn't a requirement). Similar to the L-shaped resonant structure 730, the L-shaped resonant structure 1430 still has a side capacitive coupling 1438 with the grounded chamber wall 1419 and a resonant current 1432 is induced in the L-shaped resonant structure 1430 that in turn induces direct localized effects 1434 through an inductive coupling 1437 through the dielectric ring 1426.

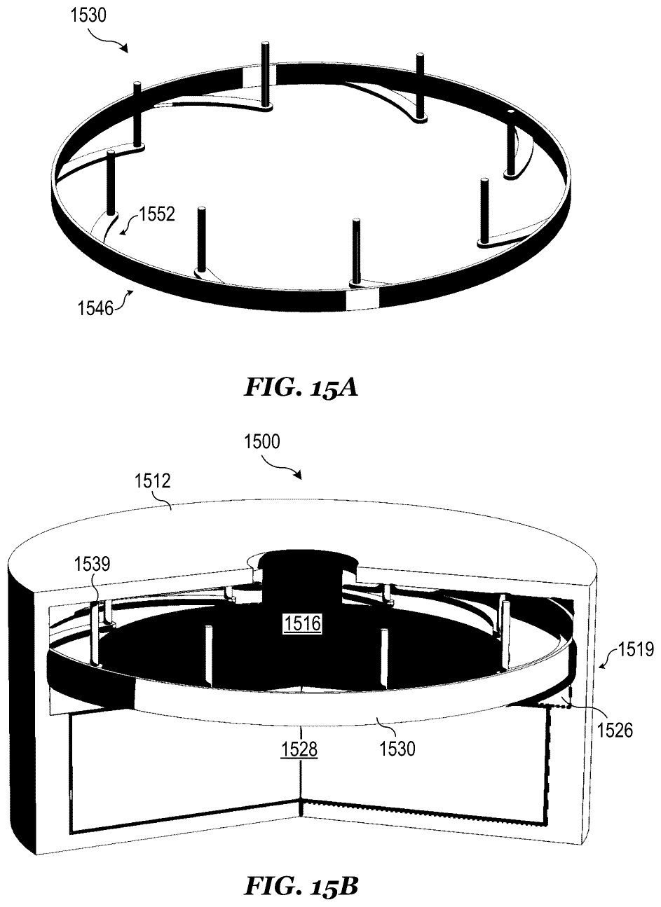

FIGS. 15A and 15B illustrate 3D views of a specific implementation of an example plasma processing apparatus that includes an L-shaped resonant structure directly connected to a grounded surface of a plasma processing chamber where FIG. 15A shows the resonant structure and FIG. 15B shows a cutaway view of the plasma processing apparatus in accordance with embodiments of the invention. Similarly labeled elements may be as previously described.

Referring to FIGS. 15A and 15B, a plasma processing apparatus 1500 includes an L-shaped resonant structure 1530 within a plasma processing chamber 1512 between a source electrode 1516 configured to generate a plasma 1528 and a grounded upper wall of the plasma processing chamber 1512. The L-shaped resonant structure 1530 has eight spiral segments 1552 that are vertically overlapping a dielectric ring 1526 electrically insulating the source electrode 1516 from the grounded chamber wall 1519. The spiral segments 1552 are each electrically coupled to a side capacitive plate 1546 and have a direct electrical coupling 1539 to a grounded upper surface of the plasma processing chamber 1512.

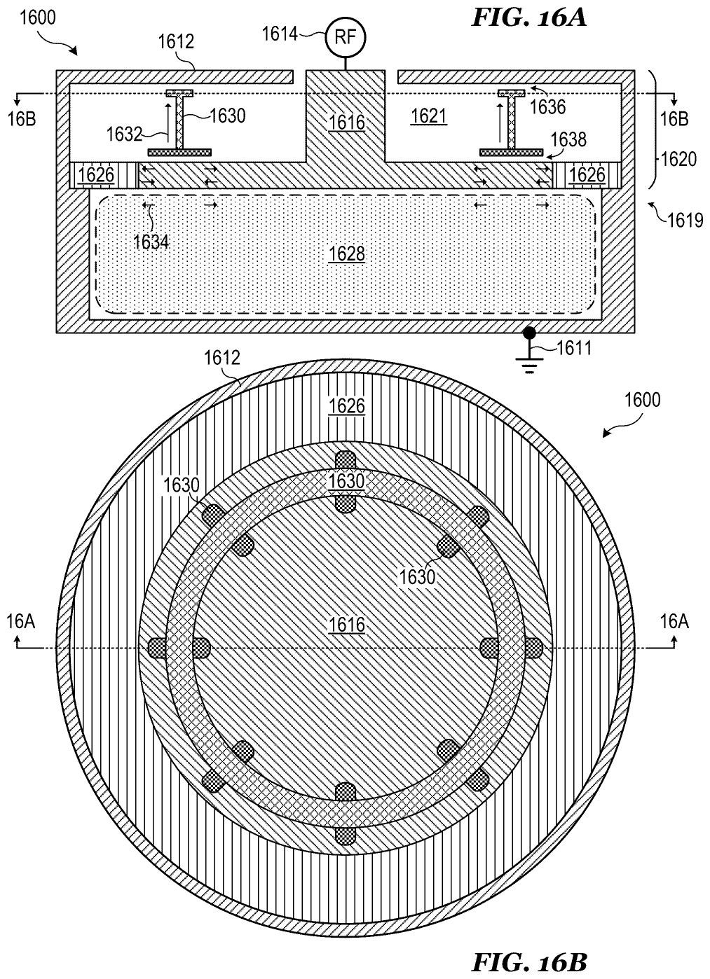

FIGS. 16A and 16B illustrate an example plasma processing apparatus that includes an I-shaped resonant structure where FIG. 16A shows a side view and FIG. 16B shows a corresponding overhead view in accordance with embodiments of the invention. The plasma processing apparatus of FIGS. 16A and 16B may be a specific implementation of other plasma processing apparatuses described herein such as the plasma processing apparatus of FIG. 1, for example. Similarly labeled elements may be as previously described.

Referring to FIGS. 16A and 16B, a plasma processing apparatus 1600 includes a ground potential 1611 electrically coupled to a grounded structure 1612 and an RF power source 1614 electrically coupled to a source electrode 1616 configured to generate a plasma 1628 using an RF field propagating through a transmission material 1621 of an RF waveguide 1620 formed by the source electrode 1616 and the grounded structure 1612. The grounded structure 1612 is implemented as a plasma processing chamber and a dielectric ring 1626 electrically insulates the source electrode 1616 from a grounded chamber wall 1619.

Now in analogy with the I-shaped resonant structure 530 of FIG. 5, an I-shaped resonant structure 1630 is included within the RF waveguide 1620 that vertically overlaps an edge region of the source electrode 1616. The source electrode 1616 generates an RF field in the RF waveguide 1620 that induces a resonant current 1632 in the I-shaped resonant structure 1630. Different from the resonant structures configured to induce inductive localized effects, the bottom segment of the I-shaped resonant structure 1630 is configured as a capacitive plate and a displacement current (the resonant current 1632) flows normal to the surface of the lower segment. As a result, the I-shaped resonant structure 1630 has a top capacitive coupling 1636 with the grounded structure 1612 and a bottom capacitive coupling 1638 the source electrode 1616 so that an indirect capacitive coupling with the plasma 1628 induces indirect localized effects 1634.

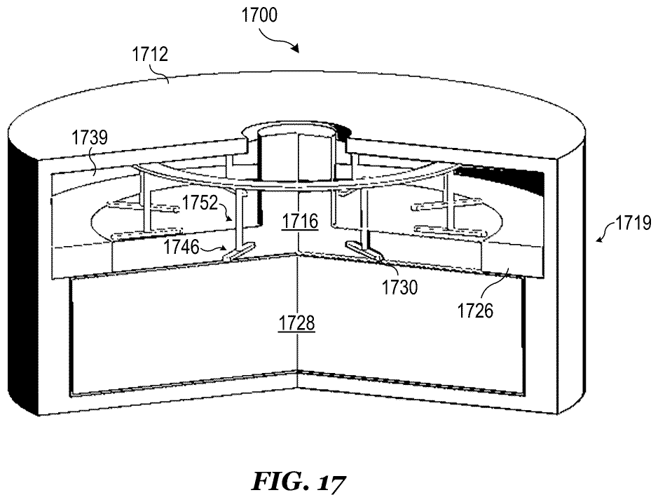

FIG. 17 illustrates a 3D cutaway view of a specific implementation of an example plasma processing apparatus that includes an I-shaped resonant structure capacitively coupled to a grounded surface of a plasma processing chamber in accordance with embodiments of the invention. Similarly labeled elements may be as previously described.

Referring to FIG. 17, a plasma processing apparatus 1700 includes an I-shaped resonant structure 1730 within a plasma processing chamber 1712 between a source electrode 1716 configured to generate a plasma 1728 and a grounded upper wall of the plasma processing chamber 1712. The I-shaped resonant structure 1730 has eight straight segments 1752 that are vertically overlapping the source electrode 1716 which is electrically insulated from the grounded chamber wall 1719 by a dielectric ring 1726. The straight segments 1752 are each electrically coupled to a respective capacitive plate 1746.

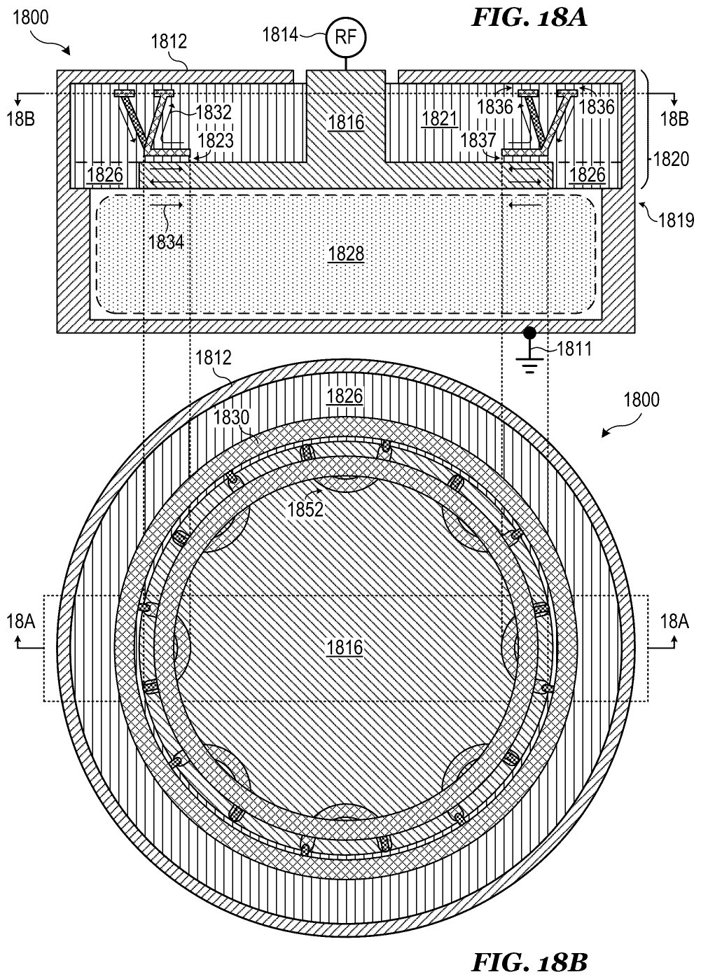

FIGS. 18A and 18B illustrate an example plasma processing apparatus that includes a horseshoe resonant structure that has eight horseshoe segments in an RF waveguide filled with a solid transmission material where FIG. 18A shows a side view and FIG. 18B shows a corresponding overhead view in accordance with embodiments of the invention. The plasma processing apparatus of FIGS. 18A and 18B may be a specific implementation of other plasma processing apparatuses described herein such as the plasma processing apparatus of FIG. 1, for example. Similarly labeled elements may be as previously described.

Referring to FIGS. 18A and 18B, a plasma processing apparatus 1800 includes a ground potential 1811 electrically coupled to a grounded structure 1812 and an RF power source 1814 electrically coupled to a source electrode 1816 configured to generate a plasma 1828 using an RF field propagating through a solid transmission material 1821 of an RF waveguide 1820 formed by the source electrode 1816 and the grounded structure 1812. The grounded structure 1812 is implemented as a plasma processing chamber and a dielectric ring 1826 electrically insulates the source electrode 1816 from a grounded chamber wall 1819.

The horseshoe resonant structure 1830 is similar to the horseshoe resonant structure 1130 and is included within the RF waveguide 1820, vertically overlapping an edge region of the source electrode 1816. However, in this implementation, two options are exemplified: the number of resonant segments and the choice of transmission material in the RF waveguide 1820. Here, there are eight horseshoe segments 1852 (as opposed to four in the previous horseshoe example, and which can of course be any desirable number). Instead of air the RF waveguide 1820, is filled with a solid transmission material 1821, within which the horseshoe resonant structure 1830 is entirely submerged (i.e., a portion of the solid transmission material 1821 acts as a dielectric support material 1823 electrically suspending the horseshoe resonant structure 1830 over the source electrode 1816). In other embodiments, the RF waveguide 1820 may be partially filled with a solid transmission material, use more than one transmission, material, etc.

As before, the horseshoe resonant structure 1830 has both ends with a capacitive coupling 1836 to an upper grounded surface of the grounded structure 1812 and a resonant current 1832 induced in the horseshoe resonant structure 1830 has an inductive coupling 1837 with the source electrode 1816 (direct inductive coupling) and an indirect inductive coupling with the plasma 1828 so as to induce indirect localized effects 1834.

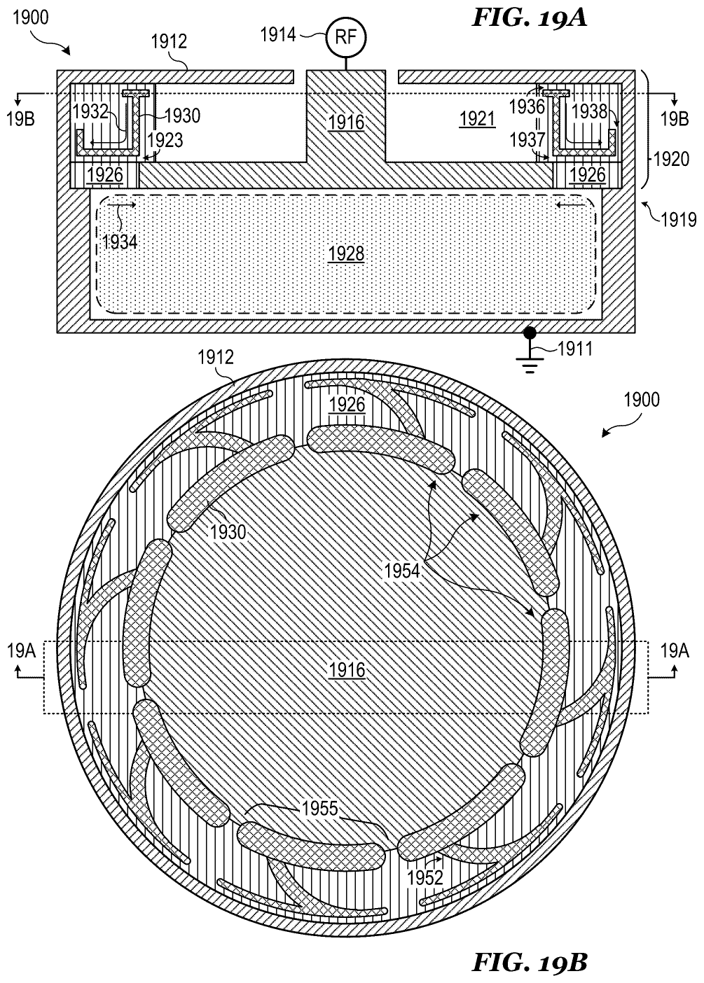

FIGS. 19A and 19B illustrate an example plasma processing apparatus that includes an L-shaped resonant structure that has multiple spiral segments in a dielectric ring where FIG. 19A shows a side view and FIG. 19B shows a corresponding overhead view in accordance with embodiments of the invention. The plasma processing apparatus of FIGS. 19A and 19B may be a specific implementation of other plasma processing apparatuses described herein such as the plasma processing apparatus of FIG. 1, for example. Similarly labeled elements may be as previously described.

Referring to FIGS. 19A and 19B, a plasma processing apparatus 1900 includes a ground potential 1911 electrically coupled to a grounded structure 1912 and an RF power source 1914 electrically coupled to a source electrode 1916 configured to generate a plasma 1928 using an RF field propagating through a transmission material 1921 of an RF waveguide 1920 formed by the source electrode 1916 and the grounded structure 1912. The grounded structure 1912 is implemented as a plasma processing chamber and a dielectric ring 1926 electrically insulates the source electrode 1916 from a grounded chamber wall 1919.

As another example of a possible implementation of a support structure, the transmission material 1921 includes a dielectric support material 1923 implemented as a dielectric ring encasing an L-shaped resonant structure 1930, which is similar to the L-shaped resonant structure 730. Different from the continuous L-shaped resonant structure 730, the L-shaped resonant structure 1930 includes a plurality of resonant structures 1954 (here, eight) that are each a separate resonant structure 1955 (i.e., each including a separate spiral segment 1952) electrically separated from other spiral segments 1952. Each of the spiral segments 1952 of the L-shaped resonant structure 1930 has a top capacitive coupling 1936 to an upper surface of the grounded structure 1912 as well as a side capacitive coupling 1938 with the grounded chamber wall 1919 and a resonant current 1932 induced in the L-shaped resonant structure 1930 induces direct localized effects 1934 through an inductive coupling 1937 through the dielectric ring 1926.

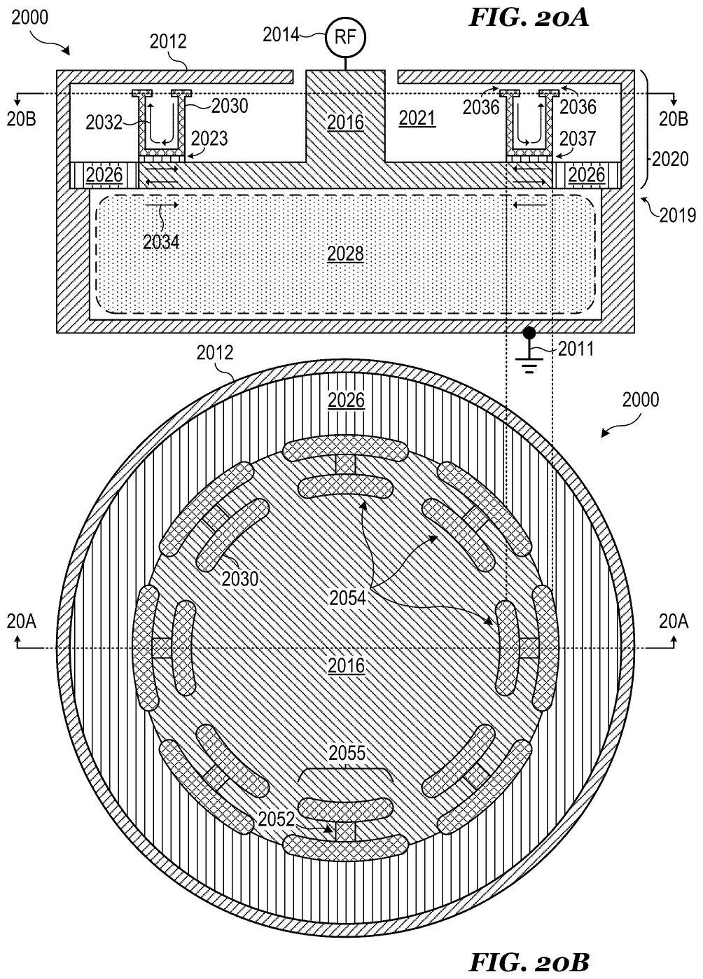

FIGS. 20A and 20B illustrate an example plasma processing apparatus that includes a U-shaped resonant structure that has multiple straight segments supported by a dielectric support material where FIG. 20A shows a side view and FIG. 20B shows a corresponding overhead view in accordance with embodiments of the invention. The plasma processing apparatus of FIGS. 20A and 20B may be a specific implementation of other plasma processing apparatuses described herein such as the plasma processing apparatus of FIG. 1, for example. Similarly labeled elements may be as previously described.

Referring to FIGS. 20A and 20B, a plasma processing apparatus 2000 includes a ground potential 2011 electrically coupled to a grounded structure 2012 and an RF power source 2014 electrically coupled to a source electrode 2016 configured to generate a plasma 2028 using an RF field propagating through a transmission material 2021 of an RF waveguide 2020 formed by the source electrode 2016 and the grounded structure 2012. The grounded structure 2012 is implemented as a plasma processing chamber and a dielectric ring 2026 electrically insulates the source electrode 2016 from a grounded chamber wall 2019.

As yet another example of a possible implementation of a support structure, the transmission material 2021 includes a dielectric support material 2023 implemented as a dielectric layer below a bottom segment of a U-shaped resonant structure 2030, which is similar to the U-shaped resonant structure 930. In analogy to the L-shaped resonant structure 1930, U-shaped resonant structure 2030 includes a plurality of resonant structures 2054 (again shown as eight here, but any number is possible) that are each a separate resonant structure 2055 (i.e., each including a separate straight segment 2052) electrically separated from other straight segments 2052. Both ends of each of the separate resonant structures 2055 of the U-shaped resonant structure 2030 has a capacitive coupling 2036 with an upper grounded surface of the grounded structure 2012, and a resonant current 2032 is induced in the U-shaped resonant structure 2030 that has an inductive coupling 2037 with the source electrode 2016 (direct inductive coupling) and an indirect inductive coupling with the plasma 2028 so as to induce indirect localized effects 2034.

FIG. 21 illustrates an example system that includes a resonant structure disposed within an RF field propagating between an upper source electrode and a grounded chamber wall, and a controller operatively coupled to at least one of the resonant structure and an RF power source that is directly coupled to the source electrode in accordance with embodiments of the invention. The system of FIG. 21 may include any of the example plasma processing apparatuses and may be used to perform any of the methods described herein, such as the plasma processing apparatus of FIG. 1 and the method of FIG. 22, for example. Similarly labeled elements may be as previously described.

Referring to FIG. 21, a system 2100 (e.g., a plasma deposition system, a plasma etching system, such as an RIE etching system, etc.) includes a substrate support 2183 disposed within a reactor chamber 2112 coupled to a ground potential 2111, such as a plasma deposition chamber or plasma etching chamber, and configured to support a substrate 2181. The reactor chamber 2112 may be any suitable plasma processing chamber, such as an CCP etching chamber, an ICP etching chamber, an RIE chamber, PE-CVD chamber, PE-ALD chamber, PE-MLD chamber, and others.

The system 2100 is configured to generate a plasma 2128 using an RF field propagating through a transmission material 2121 of an RF waveguide 2120 formed by an upper source electrode 2116 and the reactor chamber 2112. That is, an RF power source 2114 is electrically coupled (e.g., using a coaxial feed) to the upper source electrode 2116 and supplies RF source power 2118 that generates the plasma 2128 below the upper source electrode 2116 so that there is a plasma sheath 2124 at an interface between the upper source electrode 2116 and the plasma 2128. A dielectric ring 2126 electrically insulates the upper source electrode 2116 from the reactor chamber 2112. As in the example plasma processing apparatuses described herein, a resonant structure 2130 is located in the RF waveguide 2020 and vertically overlaps at least one of the upper source electrode 2116 and the dielectric ring 2126. The resonant structure 2130 is configured to induce localized effects in the plasma 2128.

A controller 2180 is operationally coupled to at least one of the RF power source 2114 and the resonant structure 2130 (e.g., an optional variable capacitor 2148 of the resonant structure 2130 or other adjustable circuit component, using a coaxial connection, for example). The controller 2180 includes a processor 2182 and a memory 2184 (i.e., a non-transitory computer-readable medium) that stores a program including instructions that, when executed by the processor 2182, perform a plasma mediated process to modify the surface of a substrate. For example, the memory 2184 may have volatile memory (e.g., random access memory (RAM)) and non-volatile memory (e.g., flash memory). Alternatively, the program may be stored in physical memory at a remote location, such as in cloud storage. The processor 2182 may be any suitable processor, such as the processor of a microcontroller, a general-purpose processor (such as a central processing unit (CPU), a microprocessor, a field-programmable gate array (FPGA), an application-specific integrated circuit (ASIC), and others.

Various other components that are not illustrated here for simplicity may also be included as may be apparent to those of skill in the art in view of this disclosure. For example, various gas sources (etchants, precursors, carrier gases, reactive gases, etc.) and valves may be included as well as exhaust valves to create a vacuum environment, temperature monitors, heaters and coolers for both the substrate of the process gases, motors to position the substrate 2181 or rotate the substrate support 2183 during processing for uniformity. When included the controller 2180 may also be operatively coupled to and configured to control one or more of these components.

FIG. 22 illustrates an example method of adjusting a plasma using a resonant structure in accordance with embodiments of the invention. The method of FIG. 22 may be combined with other methods and performed using the systems and apparatuses as described herein. For example, the method of FIG. 22 may be combined with any of the embodiments of FIGS. 1-21. Although shown in a logical order, the arrangement and numbering of the steps of FIG. 22 are not intended to be limited. The method steps of FIG. 22 may be performed in any suitable order or concurrently with one another as may be apparent to a person of skill in the art.

Referring to FIG. 22, a method 2200 of adjusting plasma includes a step 2201 of generating a plasma using RF source power that has a selected source power frequency (e.g., in the HF, VHF, or higher frequency portions of the electromagnetic spectrum). A current is induced in a resonant structure using an RF field propagated through an RF waveguide by the RF source power in a step 2202. The resonant structure is located within the RF field and is electrically insulated from the RF source power. The current in the resonant structure induces localized effects in the plasma (e.g., localized fields locally increasing the plasma density). Of course, step 2201 and step 2202 may be thought of as a single step in some cases since the current may be induced in the resonant structure the moment the RF field reaches the resonant structure. However, this may not always be the case, such as if the source power frequency is chosen to initially be a frequency that outside the resonant frequency window of the resonant structure and the source power frequency is subsequently brought into the resonant frequency window to adjust the plasma.

The method 2200 further includes an optional step 2203 of adjusting the coupling of the resonant structure with the RF field. For example, the source power frequency may be adjusted to alter the localized effects in the plasma (optional step 2204). Alternatively or additionally, the capacitance of the resonant structure may be adjusted to change the localized effects in the plasma (optional step 2205).

The coupling of the resonant structure may be adjusted in various ways. For example, the resonant structure may include a peak resonant frequency, and adjusting the localized effects in the plasma may be accomplished by adjusting the source power frequency relative to the peak resonant frequency. Without being limited by theory, one possible explanation of the peak resonant frequency is as follows. The resonant structure may be considered a collection of geometrical conductive structures that may include lossless dielectric elements inside of a closed conductive container. If Maxwell's equations for the electromagnetic fields are solved for this geometry, only a discrete set of frequencies is allowed for all boundary conditions on the conductive surfaces to be satisfied. These frequencies may be considered the resonant frequencies of the configuration. If a port is introduced into the enclosing conductive container and electromagnetic energy is introduced through this port, it might be found that there are the resonant frequencies defined above the electromagnetic fields in the vicinity of the resonant structure are enhanced relative to a situation where the frequency of the exciting electromagnetic energy is far from one of the resonant frequencies. In practice, the enclosed container may actually have lossy elements. Such elements may broaden the range of frequencies at which enhanced electromagnetic fields are generated in the vicinity of the resonant structure. However, the magnitude of the enhanced electromagnetic fields as function of frequency may still have a maximum at the resonant frequency defined above, which may then be described as the “peak resonant frequency”.

The coupling may be specifically adjusted to increase the plasma density at edge regions of the plasma, but other plasma properties may also be adjusted using the resonant structure. When the plasma density is increased in edge regions, the flatness of the plasma profile may be improved (e.g., the plasma is a center-peaked plasma without the effects of the resonant structure, and the increased plasma density in the edge regions improves the uniformity of the plasma by “flattening” the plasma profile). Taken even further, the plasma may be converted from a center-peaked plasma to an edge-peaked plasma by increasing the plasma density in the edge regions using the resonant structure.

When less RF power is diverted through the resonant structure, such as when the source power frequency is somewhat different than the peak resonant frequency of the resonant structure, the coupling between the resonant structure and the RF field may be considered weak. In a CCP system, for example, the majority of the RF power flows through the source electrode and a CCP plasma is generated. Adjusting the plasma can then take the form of adjusting the coupling from a weak coupling during which the plasma is a substantially CCP plasma to a strong coupling during which the plasma is a substantially ICP plasma. For example, the resonant structure may be directly inductively coupled to the plasma through a dielectric spacer and changing the source power frequency to be closer to the peak resonant frequency of the resonant structure may result in inductively coupled plasma being directly generated by the resonant structure. In some cases, the majority of the RF power may flow through the resonant structure resulting in a substantially ICP plasma.

Many electrical properties of the resonant structure can be adjusted to adjust the localized effects in the plasma. For example, the capacitance of the resonant structure may be adjusted using a variable capacitor of the resonant structure, by adjusting a gap between a plate of the resonant structure and another conductive surface of the RF waveguide (this could be between the plate and a grounded conductive surface of the RF waveguide, between the plate and a source electrode including a side of the RF waveguide, between the plate and a dielectric spacer separating a source electrode including one side of the RF waveguide from a grounded chamber wall, or could include moving the current-carrying element relative to the RF waveguide). Capacitive plates of the resonant structure may also be moved, such as to adjust the vertical overlap of a plate of the resonant structure and a conductive surface of the RF waveguide (between a capacitive plate of the resonant structure and a source electrode, dielectric spacer, etc.).

Example embodiments of the invention are summarized here. Other embodiments can also be understood from the entirety of the specification as well as the claims filed herein.

Example 1. A plasma processing apparatus including: a plasma processing chamber; a radio frequency (RF) waveguide, the plasma processing apparatus being configured to generate a plasma within the plasma processing chamber using an RF field propagating through the RF waveguide, the plasma including a plasma sheath extending laterally along a surface of the RF waveguide; and a resonant structure disposed in the RF field and configured to induce localized effects in the plasma using current induced in the resonant structure by the RF field.

Example 2. The plasma processing apparatus of example 1, where the resonant structure is further configured to induce inductive localized effects in the plasma by inducing electric fields in the plasma parallel to the surface of the RF waveguide.

Example 3. The plasma processing apparatus of example 1, where the resonant structure is further configured to induce capacitive localized effects in the plasma by inducing electric fields in the plasma perpendicular to the surface of the RF waveguide.

Example 4. The plasma processing apparatus of example 1, where the RF waveguide includes a source electrode including an upper conductive surface and a lower conductive surface, and a grounded conductive surface disposed above the upper conductive surface, the grounded conductive surface and the upper conductive surface together forming the RF waveguide, the plasma processing apparatus being configured to generate the plasma below the lower conductive surface using RF source power directly coupled to the source electrode and that generates the RF field.

Example 5. The plasma processing apparatus of example 4, further including: a dielectric spacer separating the source electrode from a grounded chamber wall, the resonant structure including a current-carrying element vertically overlapping one or more of the upper conductive surface and the dielectric spacer.

Example 6. The plasma processing apparatus of example 1, where the plasma is a capacitively coupled plasma (CCP).

Example 7. The plasma processing apparatus of example 1, where the RF field is generated using a source power frequency greater than about 3 MHz.

Example 8. The plasma processing apparatus of example 7, where the source power frequency is in the high frequency (HF) portion of the electromagnetic spectrum between about 3 MHz and about 30 MHz.

Example 9. The plasma processing apparatus of example 7, where the source power frequency is in the very high frequency (VHF) portion of the electromagnetic spectrum between about 30 MHz and about 300 MHz.

Example 10. The plasma processing apparatus of example 9, where the source power frequency is about 200 MHz.

Example 11. The plasma processing apparatus of example 9, where the source power frequency is about 400 MHz.

Example 12. The plasma processing apparatus of example 7, where the source power frequency is in the microwave portion of the electromagnetic spectrum between about 300 MHz and about 300 GHz.

Example 13. The plasma processing apparatus of example 12, where the source power frequency is in the ultra high frequency (UHF) portion of the electromagnetic spectrum between about 300 MHz and 3 GHz.

Example 14. The plasma processing apparatus of example 13, where the source power frequency is about 700 MHz.

Example 15. The plasma processing apparatus of example 52, where the resonant structure includes a band of resonant frequencies within which the resonant structure is configured to induce the localized effects.

Example 16. The plasma processing apparatus of example 52, where the RF waveguide includes gas as a transmission material through which the RF field propagates.

Example 17. The plasma processing apparatus of example 16, where the resonant structure is supported by a dielectric support material between the resonant structure and the RF waveguide.

Example 18. The plasma processing apparatus of example 17, where the resonant structure is disposed within the dielectric support material.

Example 19. The plasma processing apparatus of example 18, where the resonant structure is disposed entirely within the dielectric support material.

Example 20. The plasma processing apparatus of example 52, the RF waveguide is filled with a solid dielectric material as a transmission material through which the RF field propagates, the resonant structure being disposed within the solid dielectric material.

Example 21. A plasma processing apparatus including: a source electrode including an upper conductive surface and a lower conductive surface; a grounded conductive surface disposed above the upper conductive surface, the grounded conductive surface and the upper conductive surface together forming a radio frequency (RF) waveguide, the plasma processing apparatus being configured to generate a plasma below the lower conductive surface using RF source power directly coupled to the source electrode that generates an RF field propagating through the RF waveguide; and a resonant structure disposed in the RF waveguide and including a current-carrying element configured to induce localized effects in the plasma using the current induced in the current-carrying element by the RF field.

Example 22. The plasma processing apparatus of example 21, where the resonant structure vertically overlaps the source electrode.

Example 23. The plasma processing apparatus of example 22, where the resonant structure vertically overlaps an edge region of the source electrode.

Example 24. The plasma processing apparatus of example 22, where the entire resonant structure is vertically aligned with the source electrode.

Example 25. The plasma processing apparatus of example 21, further including: a dielectric spacer separating the source electrode from a grounded chamber wall, the resonant structure vertically overlapping the dielectric spacer.

Example 26. The plasma processing apparatus of example 25, where the entire resonant structure vertically overlaps the dielectric spacer.

Example 27. The plasma processing apparatus of example 25, where the current-carrying element includes a segment parallel to the dielectric spacer, the segment being inductively coupled to the plasma.

Example 28. The plasma processing apparatus of example 27, where the resonant structure is a grounded resonant structure, the current-carrying element including an end electrically connected to the grounded conductive surface.

Example 29. The plasma processing apparatus of example 25, where the current-carrying element includes a segment parallel to the dielectric spacer, the segment being capacitively coupled to the plasma.

Example 30. The plasma processing apparatus of example 21, where the resonant structure further includes a first plate that is capacitively coupled to the grounded conductive surface.

Example 31. The plasma processing apparatus of example 30, where the current-carrying element includes a U-shaped cross-section.

Example 32. The plasma processing apparatus of example 31, where a lower segment of the U-shaped cross-section being configured to induce inductive localized effects in the plasma by inducing electric fields in the plasma parallel to the lower conductive surface.

Example 33. The plasma processing apparatus of example 30, where the current-carrying element is configured to directly induce the localized effects in the plasma.

Example 34. The plasma processing apparatus of example 33, where the current-carrying element includes an L-shaped cross-section, one end of the L-shaped cross-section being electrically coupled to the grounded conductive surface, a lower segment of the L-shaped cross-section being configured to directly induce the localized effects in the plasma.

Example 35. The plasma processing apparatus of example 30, where the current-carrying element is configured to induce capacitive localized effects in the plasma by inducing electric fields in the plasma perpendicular to the lower conductive surface.

Example 36. The plasma processing apparatus of example 35, where the current-carrying element includes an I-shaped cross-section, a lower segment of the I-shaped cross-section being configured to induce the capacitive localized effects in the plasma.

Example 37. The plasma processing apparatus of example 30, where the resonant structure further includes a second plate capacitively coupled to the grounded conductive surface so that the resonant structure is electrically floating, the current-carrying element being electrically coupled to between the first plate and the second plate.

Example 38. The plasma processing apparatus of example 21, where the current-carrying element includes a non-radial portion configured as an inductive element of the resonant structure.

Example 39. The plasma processing apparatus of example 38, where the non-radial portion includes a spiral segment shape.

Example 40. The plasma processing apparatus of example 38, where the non-radial portion includes a horseshoe shape.

Example 41. The plasma processing apparatus of example 21, where the current-carrying element includes a segment parallel to and inductively coupled to the upper conductive surface.

Example 42. The plasma processing apparatus of example 21, where the current-carrying element includes a segment parallel to and capacitively coupled to the upper conductive surface.

Example 43. The plasma processing apparatus of example 42, where the current-carrying element includes a U-shaped cross-section.

Example 44. The plasma processing apparatus of example 21, where the resonant structure includes a plurality of resonant structures electrically insulated from one another, each of the plurality of resonant structures being configured to induce a respective localized effect in the plasma.

Example 45. The plasma processing apparatus of example 21, where the resonant structure is an electrically continuous structure laterally surrounding the source electrode.

Example 46. The plasma processing apparatus of example 21, where the resonant structure is electrically insulated from the RF source power.

Example 47. The plasma processing apparatus of example 46, where the resonant structure is entirely electrically insulated from the grounded conductive surface.

Example 48. The plasma processing apparatus of example 46, where the resonant structure is directly electrically connected to the grounded conductive surface.

Example 49. The plasma processing apparatus of example 21, where the resonant structure has radial symmetry about a vertical central axis of the source electrode.

Example 50. The plasma processing apparatus of example 49, where the radial symmetry is a 4-fold radial symmetry.

Example 51. The plasma processing apparatus of example 49, where the radial symmetry is an 8-fold radial symmetry.

Example 52. The plasma processing apparatus of one of examples 1 to 51, implemented as a capacitively coupled plasma (CCP) reactor including: a reactor chamber; an upper source electrode disposed in the reactor chamber; a grounded conductive surface vertically overlapping at least the upper source electrode, the grounded conductive surface being separated from the upper source electrode by a transmission material; a radio frequency (RF) power source directly coupled to both the upper source electrode and the grounded conductive surface, the RF power source being configured to generate a CCP plasma in the reactor chamber; and a resonant structure disposed in the transmission material, the resonant structure including a plate capacitively coupled to the grounded conductive surface, and a current-carrying element vertically overlapping the upper source electrode.

Example 53. The plasma processing apparatus of one of examples 1 to 51, implemented as a capacitively coupled plasma (CCP) reactor including: a reactor chamber; an upper source electrode disposed in the reactor chamber; a dielectric ring surrounding the upper source electrode; a grounded conductive surface vertically overlapping at least the upper source electrode, the grounded conductive surface being separated from the upper source electrode by a transmission material; a radio frequency (RF) power source directly coupled to both the upper source electrode and the grounded conductive surface, the RF power source being configured to generate a CCP plasma in the reactor chamber; and a resonant structure disposed in the transmission material, the resonant structure including a plate capacitively coupled to the grounded conductive surface, and a current-carrying element vertically overlapping the dielectric ring.

Example 54. A method of adjusting plasma, the method including: generating a plasma using radio frequency (RF) source power including a source power frequency that generates an RF field propagating through an RF waveguide; inducing a current in a resonant structure using the RF field, the resonant structure being located within the RF field and electrically insulated from the RF source power, the current in the resonant structure inducing localized effects in the plasma; and adjusting the localized effects in the plasma by changing one or more of the source power frequency or capacitance of the resonant structure.

Example 55. The method of example 54, where the resonant structure includes a peak resonant frequency, and where adjusting the localized effects in the plasma includes adjusting the source power frequency relative to the peak resonant frequency.

Example 56. The method of example 54, where adjusting the localized effects in the plasma includes adjusting a coupling of the resonant structure with the RF field to increase plasma density at edge regions of the plasma.

Example 57. The method of example 56, where increasing the plasma density at the edge regions improves flatness of the plasma profile.

Example 58. The method of example 56, where increasing the plasma density at the edge regions converts the plasma from a center-peaked plasma to an edge-peaked plasma.

Example 59. The method of example 56, where adjusting the coupling includes changing the coupling from a weak coupling during which the plasma is a substantially capacitively coupled plasma (CCP) to a strong coupling during which the plasma is a substantially inductively coupled plasma (ICP).

Example 60. The method of example 54, where adjusting the localized effects in the plasma includes adjusting the capacitance of the resonant structure.

Example 61. The method of example 60, where adjusting the capacitance of the resonant structure includes adjusting a variable capacitor of the resonant structure.

Example 62. The method of example 60, where adjusting the capacitance of the resonant structure includes adjusting a gap between a plate of the resonant structure and another conductive surface of the RF waveguide.

Example 63. The method of example 62, where the gap is between the plate and a grounded conductive surface of the RF waveguide.

Example 64. The method of example 62, where the resonant structure includes a current-carrying element including the plate, and where adjusting the gap includes moving the current-carrying element relative to the RF waveguide.

Example 65. The method of example 64, where the gap is between the plate and a source electrode including a side of the RF waveguide.

Example 66. The method of example 64, where the gap is between the plate and a dielectric spacer separating a source electrode including one side of the RF waveguide from a grounded chamber wall.

Example 67. The method of example 60, where adjusting the capacitance of the resonant structure includes adjusting vertical overlap of a plate of the resonant structure and a conductive surface of the RF waveguide.

Example 68. The method of example 67, where the vertical overlap is between the plate and a grounded conductive surface of the RF waveguide.

Example 69. The method of example 67, where the vertical overlap is between the plate and a source electrode including one side of the RF waveguide.

Example 70. The method of example 67, where the vertical overlap is between the plate and a dielectric spacer separating a source electrode including one side of the RF waveguide from a grounded chamber wall.

Example 71. A system including: a radio frequency (RF) waveguide including a grounded conductive surface; an RF power source coupled to the RF waveguide and configured to supply RF source power including a source power frequency; a resonant structure disposed in the RF waveguide and electrically insulated from the RF power source; and a controller operationally coupled to at least one of the RF power source and the resonant structure, the controller including a processor and a non-transitory computer-readable medium storing a program including instructions that, when executed by the processor, perform the method of claim 54.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A plasma processing apparatus comprising:
a plasma processing chamber;
a radio frequency (RF) waveguide, the plasma processing apparatus being configured to generate a plasma within the plasma processing chamber using an RF field propagating through the RF waveguide, the plasma comprising a plasma sheath extending laterally along a surface of the RF waveguide; and
a resonant structure disposed in the RF field and configured to induce localized effects in the plasma using current induced in the resonant structure by the RF field.

2. The plasma processing apparatus of claim 1, wherein the resonant structure is further configured to induce inductive localized effects in the plasma by inducing electric fields in the plasma parallel to the surface of the RF waveguide.

3. The plasma processing apparatus of claim 1, wherein the resonant structure is further configured to induce capacitive localized effects in the plasma by inducing electric fields in the plasma perpendicular to the surface of the RF waveguide.

4. The plasma processing apparatus of claim 1, wherein the RF waveguide comprises
a source electrode comprising an upper conductive surface and a lower conductive surface, and
a grounded conductive surface disposed above the upper conductive surface, the grounded conductive surface and the upper conductive surface together forming the RF waveguide, the plasma processing apparatus being configured to generate the plasma below the lower conductive surface using RF source power directly coupled to the source electrode and that generates the RF field.

5. The plasma processing apparatus of claim 4, further comprising:
a dielectric spacer separating the source electrode from a grounded chamber wall, the resonant structure comprising a current-carrying element vertically overlapping one or more of the upper conductive surface and the dielectric spacer.

6. A plasma processing apparatus comprising:
a source electrode comprising an upper conductive surface and a lower conductive surface;
a grounded conductive surface disposed above the upper conductive surface, the grounded conductive surface and the upper conductive surface together forming a radio frequency (RF) waveguide, the plasma processing apparatus being configured to generate a plasma below the lower conductive surface using RF source power directly coupled to the source electrode that generates an RF field propagating through the RF waveguide; and
a resonant structure disposed in the RF waveguide and comprising a current-carrying element configured to induce localized effects in the plasma using the current induced in the current-carrying element by the RF field.

7. The plasma processing apparatus of claim 6, wherein the resonant structure vertically overlaps an edge region of the source electrode.

8. The plasma processing apparatus of claim 7, wherein the entire resonant structure is vertically aligned with the source electrode.

9. The plasma processing apparatus of claim 6, further comprising:
a dielectric spacer separating the source electrode from a grounded chamber wall, the resonant structure vertically overlapping the dielectric spacer.

10. The plasma processing apparatus of claim 6, wherein the resonant structure further comprises a plate that is capacitively coupled to the grounded conductive surface.

11. The plasma processing apparatus of claim 10, wherein the current-carrying element comprises a U-shaped cross-section, a lower segment of the U-shaped cross-section being configured to induce inductive localized effects in the plasma by inducing electric fields in the plasma parallel to the lower conductive surface.

12. The plasma processing apparatus of claim 10, wherein the current-carrying element comprises an L-shaped cross-section, one end of the L-shaped cross-section being electrically coupled to the grounded conductive surface, a lower segment of the L-shaped cross-section being configured to directly induce the localized effects in the plasma.

13. The plasma processing apparatus of claim 10, wherein the current-carrying element comprises an I-shaped cross-section, a lower segment of the I-shaped cross-section being configured to induce capacitive localized effects in the plasma by inducing electric fields in the plasma perpendicular to the lower conductive surface.

14. The plasma processing apparatus of claim 6, wherein the resonant structure comprises a plurality of resonant structures electrically insulated from one another, each of the plurality of resonant structures being configured to induce a respective localized effect in the plasma.

15. A method of adjusting plasma, the method comprising:
generating a plasma using radio frequency (RF) source power comprising a source power frequency;
inducing a current in a resonant structure using an RF field propagated through an RF waveguide by the RF source power, the resonant structure being located within the RF field and electrically insulated from the RF source power, the current in the resonant structure inducing localized effects in the plasma; and
adjusting the localized effects in the plasma by changing one or more of the source power frequency or capacitance of the resonant structure.

16. The method of claim 15, wherein the resonant structure comprises a peak resonant frequency, and wherein adjusting the localized effects in the plasma comprises adjusting the source power frequency relative to the peak resonant frequency.

17. The method of claim 15, wherein adjusting the localized effects in the plasma comprises adjusting a coupling of the resonant structure with the RF field to increase plasma density at edge regions of the plasma.

18. The method of claim 15, wherein adjusting the localized effects in the plasma comprises adjusting the capacitance of the resonant structure.

19. The method of claim 18, wherein adjusting the capacitance of the resonant structure comprises adjusting a variable capacitor of the resonant structure.

20. The method of claim 18, wherein adjusting the capacitance of the resonant structure comprises adjusting a gap between a plate of the resonant structure and another conductive surface of the resonant structure of the RF waveguide.
